(19) United States
(12) Patent Application Publication
(10) Pub. No.: US 2018/0024182 A1
(43) Pub. Date: Jan. 25, 2018

(54) INSPECTION METHOD FOR TOUCH PANEL CONTROL SUBSTRATE, AND TOUCH PANEL CONTROLLER

(71) Applicant: SHARP KABUSHIKI KAISHA, Sakai City, Osaka (JP)

(72) Inventors: Narakazu SHIMOMURA, Sakai City (JP); Eiji NAKAUE, Sakai City (JP)

(73) Assignee: SHARP KABUSHIKI KAISHA, Sakai City, Osaka (JP)

(21) Appl. No.: 15/548,041

(22) PCT Filed: Jan. 8, 2016
(86) PCT No.: PCT/JP2016/050468

§ 371 Date: Aug. 1, 2017

(30) Foreign Application Priority Data
Feb. 27, 2015 (JP) 2015-039305

(51) Int. Cl. G01R 31/04; G06F 3/044; G06F 3/041; G01R 29/12; G01R 27/26

(52) U.S. Cl. CPC G01R 31/04; G01R 29/12; G01R 27/2605; G06F 3/0416; G06F 3/044

(57) ABSTRACT

An inspection method for a touch panel control substrate, with which inspection for mounting failure is able to be simply executed, is provided. On the basis of a response that is obtained, in response to a drive signal supplied to a first drive line terminal (101E), in a different drive line terminal (102E, 103E), an electrical connection state between the first drive line terminal (101E) and the drive line terminal (102E, 103E) is detected.

### TECHNICAL FIELD

The present invention relates to an inspection method for a touch panel control substrate, and a touch panel controller, and, particularly, relates to an inspection method for a touch panel control substrate by which a touch panel that uses an electrostatic capacitance method is driven, and a touch panel controller.

### BACKGROUND ART

Conventionally, various methods have been known as methods for detecting a touched position in a touch panel device. Particularly, a touch panel device that uses an electrostatic capacitance method, which utilizes an electrostatic capacitance, is able to allow a direct touch operation with a fingertip of an operator or a touch operation with the use of a simple stylus pen that is made of an electrically conductive material, and therefore is very convenient.

In general, a touch panel device that uses an electrostatic capacitance method includes a touch panel main body having a structure in which a plurality of drive lines (first electrodes) and a plurality of sense lines (second electrodes) are arranged so as to intersect each other three-dimensionally and a touch panel controller with which the touch panel main body is controlled.

The touch panel controller is connected to a touch panel via a connector, and applies drive signals to the drive lines and detects a touched position on the basis of sense signals (response signals) generated in the sense lines. Specifically, when an electrically conductive object approaches or makes contact with the touch panel main body, electrostatic capacitances generated at intersections of the plurality of drive lines and the plurality of sense lines change. From sense signals generated in the sense lines, the touch panel controller detects a signal strength at coordinates of each of intersecting positions of the drive lines and the sense lines in the touch panel main body, and is thereby able to detect a touched position.

Generally, a touch panel controller and a connector are mounted on a printed substrate or a flexible substrate in order to form a touch panel control substrate. In an inspection process that is performed while the touch panel control substrate is manufactured, a touch panel main body is connected to the touch panel control substrate, and quality of the touch panel control substrate is judged on the basis of whether or not a touched position when the touch panel main body is touched is able to be detected.

In PTL 1, a touch panel inspection device that includes a probe that can be made to touch a touch panel main body with a pressing force similar to that of a human finger is described as an inspection device used for inspection of such a touch panel. According to the touch panel inspection device of PTL 1, it is possible to efficiently and accurately execute inspection of the touch panel main body.

### CITATION LIST

### Patent Literature

PTL 1: Japanese Unexamined Patent Application Publication No. 2013-174939 (published on Sep. 5, 2013)

### SUMMARY OF INVENTION

### Technical Problem

For a printed substrate (or a flexible substrate), a touch panel controller, and the like that constitute a touch panel control substrate, detailed quality inspection is executed by a supplier.

Thus, in quality inspection of the touch panel control substrate, only inspection for “mounting failure (open circuit failure, short circuit failure)” that is caused in a manufacturing process of the touch panel control substrate is required to be executed, and it is not always necessary to execute inspection that an inspection executor performs by touching a touch panel main body with his/her own finger nor detailed inspection using the touch panel inspection device of PTL 1.

On the other hand, in order to execute the inspection using the touch panel inspection device of PTL 1 or the conventional inspection that an inspection executor performs by touching a touch panel main body with his/her own finger, it is necessary to connect the touch panel main body to the touch panel control substrate, and it takes several tens of seconds per one product normally. Moreover, time for the touch panel inspection device of PTL 1 or time for the inspection executor to touch the touch panel main body with his/her own finger is required, and it takes several tens of seconds to several minutes per one product normally. In this manner, there is a problem that, with a conventional inspection method, inspection time increases and costs of manufacturing a touch panel control substrate increases.

Furthermore, in recent years, a panel size of a touch panel is increasing. In a large-sized touch panel, the number of drive lines and the number of sense lines increase and an area to be touched is enlarged correspondingly thereto, so that there is a problem that, with the inspection method that is executed by touching a touch panel main body, the manufacturing costs further increases.

The invention is made in order to solve the aforementioned problems, and an object thereof is to provide an inspection method for a touch panel control substrate and a touch panel controller with which inspection for mounting failure in a process of mounting a touch panel controller and a connector on a substrate is able to be simply executed without connecting the touch panel controller to a touch panel main body via the connector to drive the touch panel main body.

### Solution to Problem

In order to solve the aforementioned problems, an inspection method for a touch panel control substrate according to an aspect of the invention is an inspection method for a touch panel control substrate including a touch panel controller that supplies, via a connector, a drive signal to a plurality of signal lines provided in a touch panel main body, including a supplying step of supplying the drive signal to a plurality of connection terminals each of which is electrically connected to each of the signal lines via the connector, and a detecting step of detecting, on the basis of each response obtained, in response to the drive signal supplied to a connection terminal among the connection terminals, in connection terminals other than the connection terminal, an electrical connection state between the connection terminal and each of the other connection terminals.

Moreover, in order to solve the aforementioned problem, an inspection method for a touch panel control substrate according to an aspect of the invention is an inspection method for a touch panel control substrate including a touch panel controller that supplies, via a connector, a drive signal to a plurality of signal lines provided in a touch panel main body, including a supplying step of supplying the drive signal to a connection terminal that is electrically connected to the signal lines via the connector, and a detecting step of measuring an electrostatic capacitance value of the connection terminal to which the drive signal is supplied and detecting, on the basis of the electrostatic capacitance value, an electrical connection state between the connection terminal and each of other connection terminals.

Moreover, in order to solve the aforementioned problems, a touch panel controller according to an aspect of the invention is a touch panel controller that supplies, via a connector, a drive signal to a plurality of signal lines provided in a touch panel main body, including a plurality of connection terminals each of which is electrically connected to each of the signal lines via the connector, a drive circuit that supplies the drive signal to the connection terminals, and a detection unit that detects, on the basis of each response obtained, in response to the drive signal supplied to a connection terminal among the connection terminals, in connection terminals other than the connection terminal, an electrical connection state between the connection terminal and each of the other connection terminals.

### Advantageous Effects of Invention

According to an aspect of the invention, it is possible to provide an inspection method for a touch panel control substrate and a touch panel controller with which inspection for mounting failure in a process of mounting a touch panel controller and a connector on a substrate is simply performed without connecting the touch panel controller to a touch panel main body via the connector to drive the touch panel main body.

### BRIEF DESCRIPTION OF DRAWINGS

FIG. 1 is a schematic view illustrating each configuration of a touch panel device according to Embodiment 1 of the invention.

FIG. 2 is a schematic view illustrating a configuration of a touch pane controller.

FIG. 3 is a block diagram illustrating a schematic configuration of the touch panel controller according to Embodiment 1 of the invention.

FIG. 4 is a view illustrating a configuration and an operation of an inverter circuit as an example of a drive circuit.

FIG. 5 is a view illustrating a configuration and an operation of a comparator circuit as an example of a voltage measuring circuit.

FIG. 6 is a block diagram illustrating a schematic configuration of a touch panel controller according to Embodiment 2 of the invention.

FIG. 7 is a block diagram illustrating a schematic configuration of a touch panel controller according to Embodiment 3 of the invention.

FIG. 8 is a block diagram illustrating a schematic configuration of a touch panel controller according to Embodiment 4 of the invention.

FIG. 9 is a block diagram illustrating a schematic configuration of a touch panel controller according to Embodiment 5 of the invention.

FIG. 10 is a view illustrating a configuration and an operation of an analog integrator as an example of a capacitance detection circuit.

FIG. 11 is a block diagram illustrating a schematic configuration of a touch panel controller according to Embodiment 6 of the invention.

FIG. 12 is a block diagram illustrating a schematic configuration of a touch panel controller according to Embodiment 7 of the invention.

FIG. 13 is a block diagram illustrating a schematic configuration of a touch panel controller according to Embodiment 8 of the invention.

FIG. 14 is a block diagram illustrating a schematic configuration of a touch panel device according to Embodiment 9 of the invention.

FIG. 15 is a circuit diagram illustrating a configuration of a multiplexer.

FIG. 16 is a block diagram illustrating a schematic configuration of a touch panel control substrate at a time of inspection for short circuit failure.

FIG. 17 is a block diagram illustrating a schematic configuration of a touch panel control substrate at a time of inspection for disconnection failure.

### DESCRIPTION OF EMBODIMENTS

### Embodiment 1

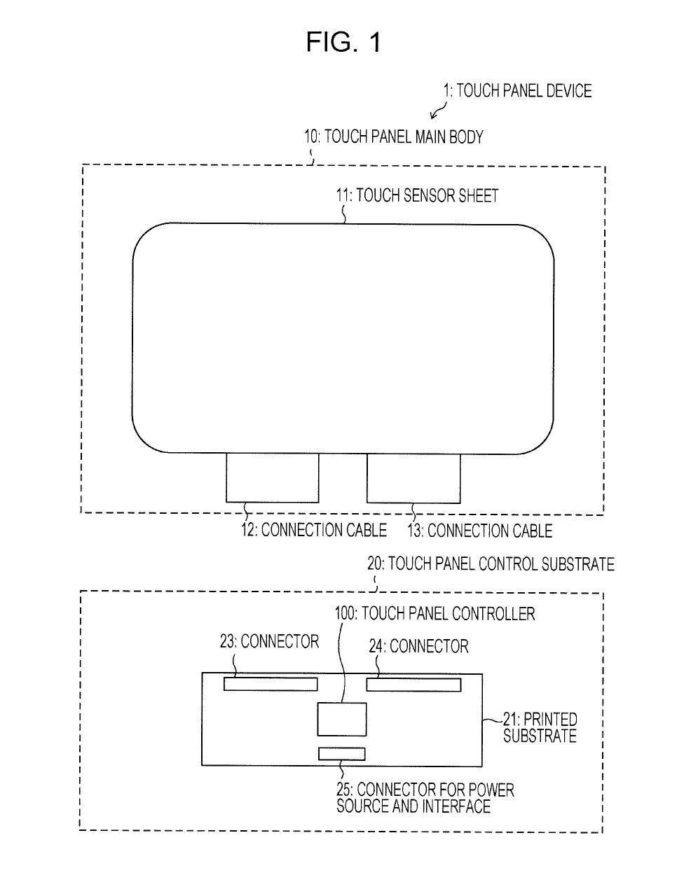

Hereinafter, an embodiment of the invention will be described in detail on the basis of FIG. 1 to FIG. 5.

FIG. 1 is a schematic view illustrating each configuration of a touch panel device 1 according to Embodiment 1 of the invention. The touch panel device 1 includes a touch panel main body 10 and a touch panel control substrate 20.

The touch panel main body 10 includes a touch sensor sheet 11 and connection cables 12 and 13 used for connection with the touch panel control substrate 20.

In the touch sensor sheet 11, a plurality of drive lines (signal lines) and a plurality of sense lines (signal lines) which are not illustrated are provided so as to intersect each other three-dimensionally.

The touch panel control substrate 20 includes, on a printed substrate 21, a touch panel controller 100, connectors 23 and 24 to which the connection cables 12 and 13 of the touch sensor sheet 11 are connected, and a connector for a power source and an interface 25.

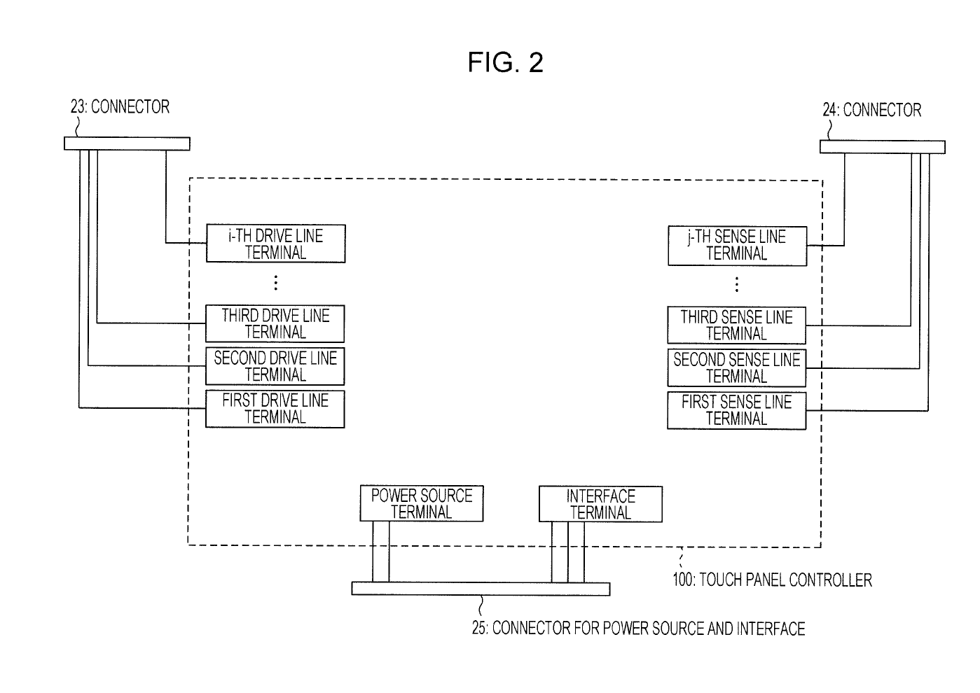

FIG. 2 is a schematic view illustrating a configuration of the touch panel controller.

As illustrated in FIG. 2, the touch panel controller 100 includes terminals (drive line terminals) which are electrically connected to the drive lines of the touch panel main body 10 and by which drive signals are applied to the drive lines, terminals (sense line terminals) which are electrically connected to the sense lines of the touch panel main body 10 and by which sense signals (response signals) generated in the sense lines are received, a power source terminal, and an interface terminal. The drive line terminals and the sense line terminals are connected to the connectors 23 and 24 used for connection with the touch sensor sheet 11. Moreover, the power source terminal and the interface terminal are connected to the connector for a power source and an interface 25.

In a conventional inspection process, the touch panel control substrate 20 is connected to the touch panel main body 10 via the connection cables 12 and 13 and the connectors 23 and 24, and a personal computer, an inspection device for examination, or the like is connected to the touch panel control substrate 20 via the connector for a power source and an interface 25, and, in a state where a power source and a control signal are connected, inspection is executed by touching a surface of the touch sensor sheet 11 with a jig for touching or a finger of an inspection executor.

Whereas, in the touch panel device 1 of the present embodiment, the touch panel controller 100 includes a characteristic configuration which will be described below, so that it is possible to simply execute inspection for mounting failure in a mounting process of the touch panel control substrate 20 without connecting the touch panel controller 100 to the touch panel main body 10 to drive the touch panel main body 10.

### <Configuration of Touch Panel Controller>

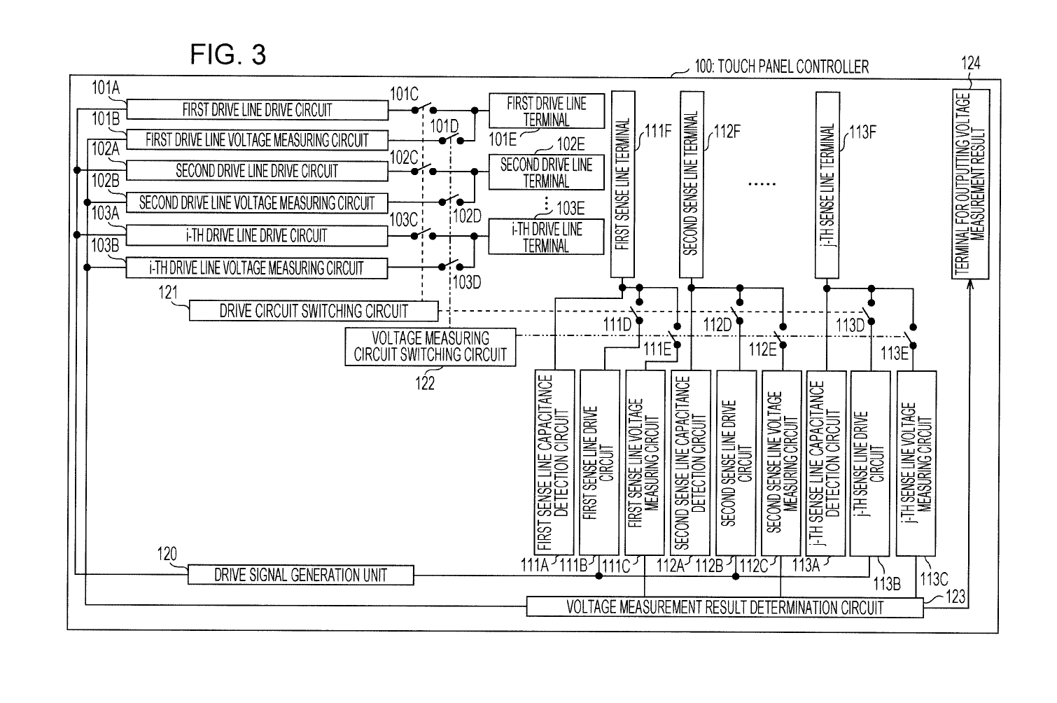

FIG. 3 is a block diagram illustrating a schematic configuration of the touch panel controller of the present embodiment. The touch panel controller 100 includes i drive line terminals 101E, 102E, and 103E (connection terminals), j sense line terminals 111F, 112F, and 113F (connection terminals), and a terminal for outputting a voltage measurement result 124. In the touch panel device 1, each of the i drive line terminals is connected to each of the drive lines of the touch panel main body 10, and each of the j terminals of a sense line is connected to each of the sense lines of the touch panel main body 10.

Switches 101C, 102C, and 103C that switch connection between the drive line terminals and drive line drive circuits 101A, 102A, and 103A, and switches 101D, 102D, and 103D that switch connection between the drive line terminals and drive line voltage measuring circuits 101B, 102B, and 103B (detection units, voltage measuring units) are connected to the drive line terminals 101E, 102E, and 103E, respectively.

Sense line capacitance detection circuits 111A, 112A, and 113A, switches 111D, 112D, and 113D that switch connection between the sense line terminals and sense line drive circuits 111B, 112B, and 113B, and switches 111E, 112E, and 113E that switch connection between the sense line terminals and sense line voltage measuring circuits 111C, 112C, and 113C (detection units, voltage measuring units) are connected to the sense line terminals 111F, 112F, and 113F, respectively.

A drive circuit switching circuit 121 is connected to the switches 101C, 102C, and 103C that switch the connection between the drive line terminals and drive line drive circuits and the switches 111D, 112D, and 113D that switch the connection between the sense line terminals and the sense line drive circuits.

A drive signal generation unit 120 is connected to the drive line drive circuits 101A, 102A, and 103A and the sense line drive circuits 111B, 112B, and 113B.

A voltage measuring circuit switching circuit 122 is connected to the switches 101D, 102D, and 103D that switch the connection between the drive line terminals and the drive line voltage measuring circuits and the switches 111E, 112E, and 113E that switch the connection between the sense line terminals and the sense line voltage measuring circuits.

A voltage measurement result determination circuit 123 (detection unit, operation unit) is connected to the drive line voltage measuring circuits 101B, 102B, and 103B and the sense line voltage measuring circuits 111C, 112C, and 113C. The terminal for outputting a voltage measurement result 124 is connected to the voltage measurement result determination circuit 123.

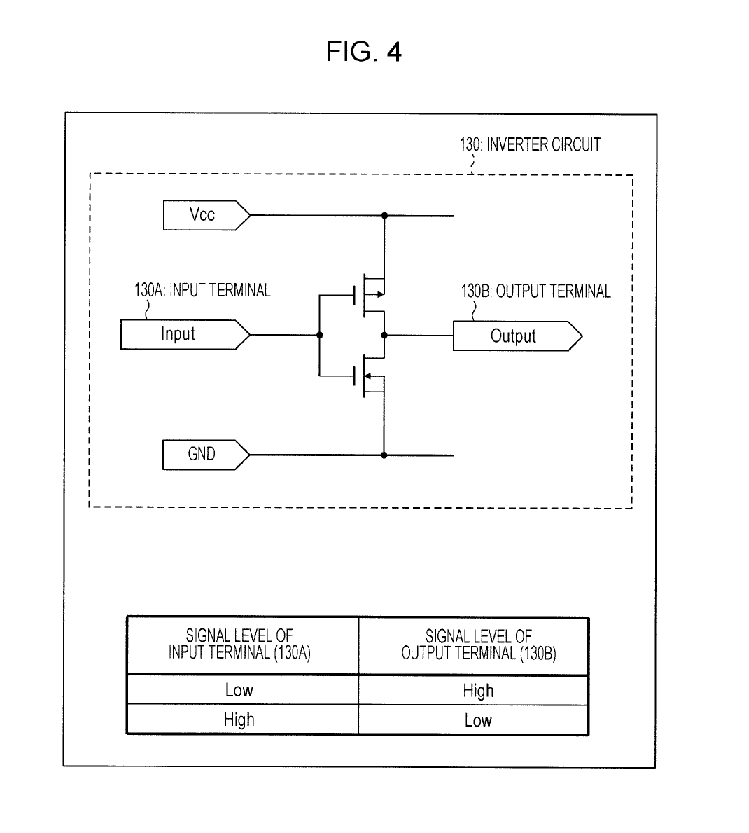

FIG. 4 is a view illustrating a configuration and an operation of an inverter circuit as an example of a drive circuit.

A drive line drive circuit supplies a drive signal to a drive line terminal, and a sense line drive circuit supplies a drive signal to a sense line drive terminal.

The inverter circuit 130 illustrated in FIG. 4 can be used as each of the drive line drive circuits 101A, 102A, and 103A, for example. Similarly, the inverter circuit 130 illustrated in FIG. 4 can be used as each of the sense line drive circuits 111B, 112B, and 113B.

As illustrated in FIG. 4, the inverter circuit 130 is formed of a PMOS transistor and an NMOS transistor. In the inverter circuit 130, when a signal of a Low level is input to an input terminal 130A, a signal of a High level is output to an output terminal 130B, and, when a signal of the High level is input to the input terminal 130A, a signal of the Low level is output to the output terminal 130B.

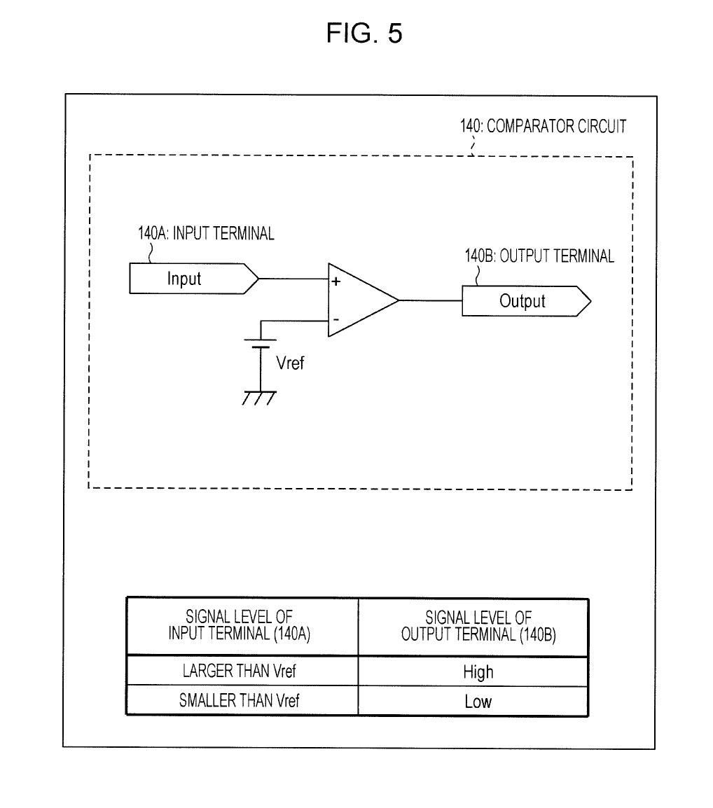

FIG. 5 is a view illustrating a configuration and an operation of a comparator circuit as an example of a voltage measuring circuit.

The comparator circuit 140 illustrated in FIG. 5 can be used as each of the drive line voltage measuring circuits 101B, 102B, and 103B and each of the sense line voltage measuring circuits 111C, 112C, and 113C, for example.

The comparator circuit 140 compares a voltage value of an input terminal 140A and a voltage value of a reference voltage Vref. In a case where the voltage of the input terminal is larger than Vref, a High level is output to an output terminal 140B, and, in a case where the voltage of the input terminal is smaller than Vref, a Low level is output to the output terminal 140B.

As described below, only whether or not voltages of the drive line terminals 101E, 102E, and 103E or the sense line terminals 111F, 112F, and 113F are 0 V is required to be determined in the voltage measuring circuits 101B, 102B, 103B, 111C, 112C, and 113C, so that a value that exceeds 0 V, for example, such as 0.1 V, may be selected as the reference voltage Vref.

The voltage measurement result determination circuit 123 successively outputs output results of the voltage measuring circuits 101B, 102B, 103B, 111C, 112C, and 113C to the terminal for outputting a voltage measurement result 124. Alternatively, the voltage measurement result determination circuit 123 may perform a logical operation on output levels of the voltage measuring circuits 101B, 102B, 103B, 111C, 112C, and 113C and output the result to the terminal for outputting a voltage measurement result 124.

For example, in a case where an OR operation (operation of a logical sum) is executed by the voltage measurement result determination circuit 123, when the High level is output in at least one voltage measuring circuit among the plurality of voltage measuring circuits, the High level is output to the terminal for outputting a voltage measurement result 124. In a case where an AND operation (operation of a logical product) is executed by the voltage measurement result determination circuit 123, when the Low level is indicated in at least one voltage measuring circuit among the plurality of voltage measuring circuits, the Low level is output to the terminal for outputting a voltage measurement result 124.

### <Inspection Method for Touch Panel Control Substrate>

The touch panel controller 100 having the above-described structure is mounted on the touch panel control substrate 20. The touch panel controller 100 includes the plurality of drive line terminals and the plurality of sense line terminals, and, in a case where any of the terminals is short-circuited to another terminal, short circuit failure is caused. Moreover, in a case where electrical connection between any of the terminals and the connector 23 or 24 that is mounted on the touch panel control substrate is disconnected (open-circuited), disconnection failure (open circuit failure) is caused.

A method for executing, without connecting the touch panel main body 10, inspection for “mounting failure (open circuit failure, short circuit failure)” that is caused in a manufacturing process of the touch panel control substrate will be described below.

The switches 101C, 102C, 103C, 111D, 112D, and 113D are successively switched with the use of the drive circuit switching circuit 121, and a signal (drive signal) of the High level is output from one of the plurality of drive line terminals and the plurality of sense line terminals (supplying step).

Then, the voltage measuring circuit switching circuit 122 successively switches the switches 101D, 102D, 103D, 111E, 112E, and 113E, or causes all of the terminals to be connected, and the voltage measuring circuits measure the voltages of the plurality of drive line terminals and the plurality of sense line terminals (detecting step) and each of the voltage measuring circuits outputs either of two values (High or Low) that indicates the presence or absence of an electrical connection between terminals.

At this time, control is performed so that a switch that connects a terminal outputting a signal of the High level and a voltage measuring circuit of the terminal does not perform connection.

### <Short Circuit Failure>

In a case where the touch panel control substrate 20 has short circuit failure, a signal of the High level output from the touch panel controller 100 is input (returned) to a different terminal (another connection terminal) of the touch panel controller 100 via a point of the failure of the touch panel control substrate 20. A voltage to be input to the different terminal of the touch panel controller 100 depends on a short circuit state in the touch panel control substrate 20, and is a value which exceeds 0 V.

The signal input via the point of the failure of the touch panel control substrate 20 is measured by a voltage measuring circuit. Since the level of the input signal exceeds 0 V, the voltage measuring circuit outputs a signal of the High level (voltage measurement result outputting step). A measurement result of the voltage measuring circuit is output to the terminal for outputting a voltage measurement result 124 via the voltage measurement result determination circuit 123. When an OR operation is executed by the voltage measurement result determination circuit 123 (operation step), the High level is output to the terminal for outputting a voltage measurement result 124.

As above, in a case where short circuit failure is caused, the High level is output to the terminal for outputting a voltage measurement result 124.

### <Disconnection Failure>

Inspection as to whether the touch panel control substrate has disconnection failure (open circuit failure) is able to be easily executed by using a jig, such as a short circuit cable, by which all terminals of the connectors 23 and 24 mounted on the touch panel control substrate are short-circuited.

Specifically, by connecting the short circuit cable to the connectors 23 and 24 on the outside of the touch panel control substrate, the drive lines and the sense lines are brought into a short-circuited state on purpose, and the inspection is started in a state where each of the terminals is short-circuited.

In a state where electrical connection is disconnected (open-circuited) in the touch panel control substrate 20, a signal of the High level output from the touch panel controller 100 does not reach the connector 23 nor the connector 24 mounted on the touch panel control substrate 20. Though the drive lines and the sense lines are short-circuited to the connectors 23 and 24 by using a jig such as the short circuit cable, the signal of the High level does not reach the connector 23 nor the connector 24 and therefore is not input (returned) to a different terminal of the touch panel controller. Thus, a voltage to be input to the different terminal of the touch panel controller 100 is 0 V.

Since the level of the input signal is 0 V, the voltage measuring circuit outputs a signal of the Low level. A measurement result of the voltage measuring circuit is output to the terminal for outputting a voltage measurement result 124 via the voltage measurement result determination circuit 123. When an AND operation is executed by the voltage measurement result determination circuit 123 (operation step), the Low level is output to the terminal for outputting a voltage measurement result 124.

As above, in a case where disconnection failure (open circuit failure) is caused, the Low level is output to the terminal for outputting a voltage measurement result 124.

As described above, the touch panel controller 100 includes the drive line terminals, the drive line drive circuits, the drive line voltage measuring circuits, the switches that switch the connection between the drive line terminals and the drive line drive circuits, the switches that switch the connection between the drive line terminals and the drive line voltage measuring circuits, the sense line terminals, the sense line drive circuits, the sense line voltage measuring circuits, the switches that switch the connection between the sense line terminals and the sense line drive circuits, the switches that switch the connection between the sense line terminals and the sense line voltage measuring circuits, the drive circuit switching circuit, the drive signal generation unit, the voltage measuring circuit switching circuit, the voltage measurement result determination circuit, and the terminal for outputting a voltage measurement result.

The touch panel controller 100 incorporates a test function that a signal for drive is successively output to the drive line terminals and the sense line terminals and voltages of terminals other than the terminal for which output is performed are measured to output a measurement result on the basis of a voltage measurement result thereof. That is, the drive line voltage measuring circuits, the sense line voltage measuring circuits, and the voltage measurement result determination circuit constitute a detection unit, and the detection unit detects an electrical connection state (short circuit or disconnection) between the drive line terminals or the sense line terminals on the basis of each response obtained, in response to a signal of the High level supplied to a drive line terminal or a sense line terminal, in the other drive line terminals or the other sense line terminals.

By incorporating the aforementioned test function, it is possible to execute, without connecting the touch panel main body 10, inspection for “mounting failure (open circuit failure, short circuit failure)” that is caused in the manufacturing process of the touch panel control substrate 20.

### Embodiment 2

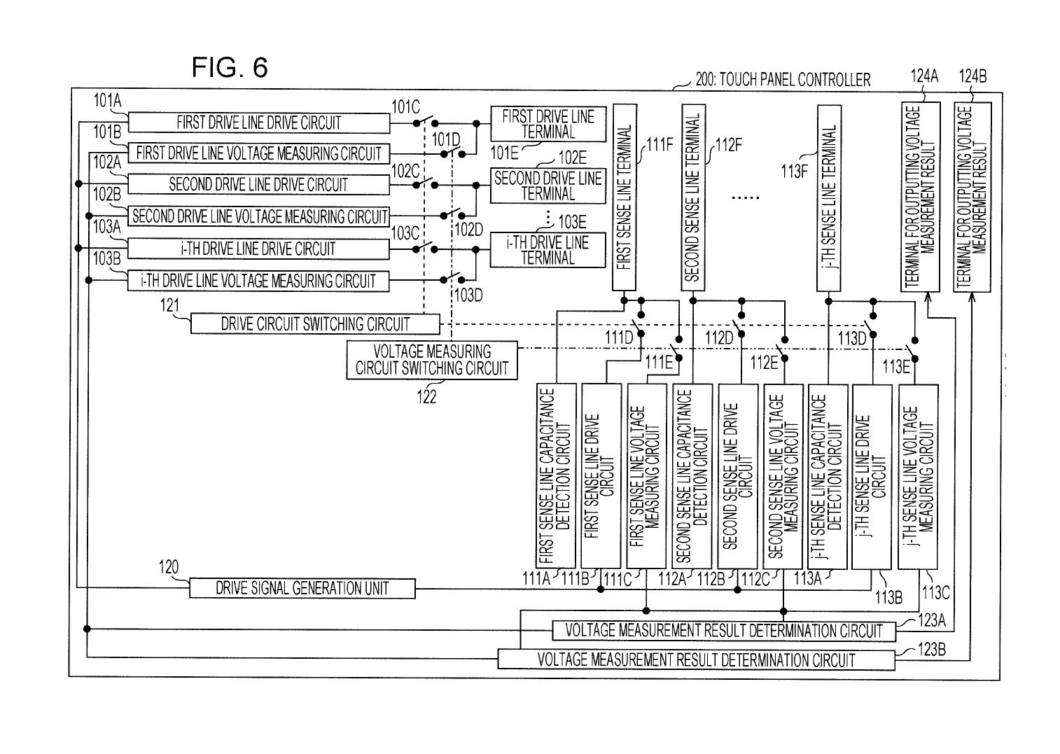

Another embodiment of the invention will be described on the basis of FIG. 6. Note that, for convenience of description, the same reference signs are assigned to members having the same functions as those of the members described in the aforementioned embodiment, and description thereof will be omitted.

FIG. 6 is a block diagram illustrating a schematic configuration of a touch panel controller of the present embodiment.

In a touch panel controller 200, the voltage measurement result determination circuit and the terminal for outputting a voltage measurement result are changed from those of the configuration of the touch panel controller 100 in Embodiment 1, which is illustrated in FIG. 3. Specifically, the touch panel controller 200 includes two voltage measurement result determination circuits 123A and 123B and two terminals for outputting a voltage measurement result 124A and 124B.

The voltage measurement result determination circuit 123A (first operation unit) executes an OR operation for a plurality of voltage measurement results, and outputs an operation result to the terminal for outputting a voltage measurement result 124A. The voltage measurement result determination circuit 123B (second operation unit) executes an AND operation for the plurality of voltage measurement results, and outputs an operation result to the terminal for outputting a voltage measurement result 124B.

In a case where short circuit failure is caused, at least one of the plurality of voltage measuring circuits outputs a signal of the High level. When the OR operation is executed by the voltage measurement result determination circuit 123A, a signal of the High level is output to the terminal for outputting a voltage measurement result 124A.

In a case where disconnection failure (open circuit failure) is caused, at least one of the plurality of voltage measuring circuits outputs a signal of the Low level. When the AND operation is executed by the voltage measurement result determination circuit 123B, a signal of the Low level is output to the terminal for outputting a voltage measurement result 124B.

Accordingly, in a case where a signal of the High level is output to the terminal for outputting a voltage measurement result 124A, it is possible to judge that short circuit failure is caused, and, in a case where a signal of the Low level is output to the terminal for outputting a voltage measurement result 124B, it is possible to judge that disconnection failure (open circuit failure) is caused.

The touch panel controller 100 of Embodiment 1 includes only one voltage measurement result determination circuit, and is therefore able to execute inspection for only either of short circuit failure and disconnection failure (open circuit failure). On the other hand, the touch panel controller 200 of the present embodiment includes the plurality of voltage measurement result determination circuits and the plurality of terminals for outputting a voltage measurement result so as to be able to execute inspection for both of short circuit failure and disconnection failure (open circuit failure).

Thus, it is possible to execute inspection for failure of both of short circuit failure and disconnection failure (open circuit failure), so that quality of the touch panel control substrate is improved.

### Embodiment 3

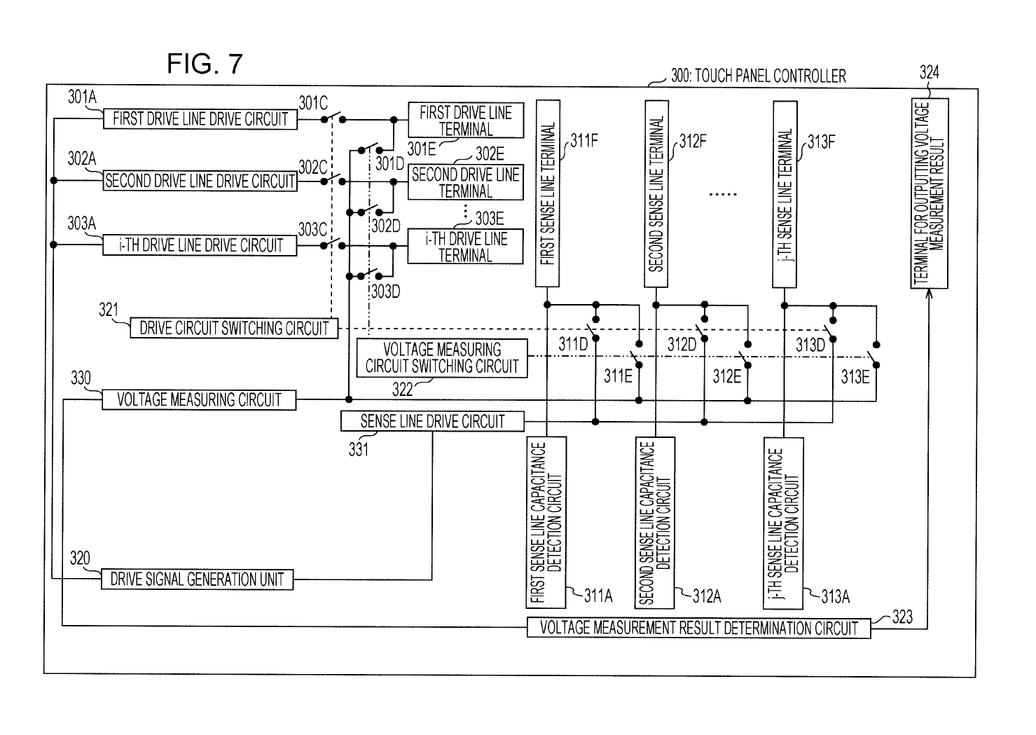

Another embodiment of the invention will be described on the basis of FIG. 7. Note that, for convenience of description, the same reference signs are assigned to members having the same functions as those of the members described in the aforementioned embodiments, and description thereof will be omitted.

FIG. 7 is a block diagram illustrating a schematic configuration of a touch panel controller of the present embodiment. A touch panel controller 300 includes i drive line terminals 301E, 302E, and 303E, j sense line terminals 311F, 312F, and 313F, and a terminal for outputting a voltage measurement result 324.

Switches 301C, 302C, and 303C that switch connection between the drive line terminals and drive line drive circuits 301A, 302A, and 303A and switches 301D, 302D, and 303D that switch connection between the drive line terminals and a voltage measuring circuit 330 (voltage measuring unit) are connected to the drive line terminals 301E, 302E, and 303E, respectively.

Sense line capacitance detection circuits 311A, 312A, and 313A, switches 311D, 312D, and 313D that switch connection between the sense line terminals and a sense line drive circuit 331, and switches 311E, 312E, and 313E that switch connection between the sense line terminals and the voltage measuring circuit 330 are connected to the sense line terminals 311F, 312F, and 313F, respectively.

A drive circuit switching circuit 321 is connected to the switches 301C, 302C, and 303C that switch the connection between the drive line terminals and the drive line drive circuits and the switches 311D, 312D, and 313D that switch the connection between the sense line terminals and the sense line drive circuit.

A drive signal generation unit 320 is connected to the drive line drive circuits 301A, 302A, and 303A and the sense line drive circuit 331.

A voltage measuring circuit switching circuit 322 is connected to the switches 301D, 302D, and 303D that switch the connection between the drive line terminals and the voltage measuring circuit and the switches 311E, 312E, and 313E that switch the connection between the sense line terminals and the voltage measuring circuit.

A voltage measurement result determination circuit 323 is connected to the voltage measuring circuit 330. A terminal for outputting a voltage measurement result 324 is connected to the voltage measurement result determination circuit 323.

It is also possible to use the same circuit as each of the drive line drive circuits 301A, 302A, and 303A for the sense line drive circuit 331. Specifically, the inverter circuit 130, as illustrated in FIG. 4, which is formed of a PMOS transistor and an NMOS transistor may be used as each of these drive circuits.

In the inverter circuit 130, when a signal of the Low level is input to the input terminal 130A, a signal of the High level is output to the output terminal 130B, and, when a signal of the High level is input to the input terminal 130A, a signal of the Low level is output to the output terminal 130B.

The comparator circuit 140 as illustrated in FIG. 5 may be used as the voltage measuring circuit 330. The comparator circuit 140 compares a voltage value of the input terminal 140A and a voltage value of the reference voltage Vref. In a case where the voltage of the input terminal is larger than Vref, the High level is output to the output terminal 140B, and, in a case where the voltage of the input terminal is smaller than Vref, the Low level is output to the output terminal 140B.

As described above, only whether or not voltages of the drive line terminals 301E, 302E, and 303E or the sense line terminals 311F, 312F, and 313F are 0 V is required to be determined in the voltage measuring circuit 330, so that a value that exceeds 0 V, for example, such as 0.1 V, may be selected as the reference voltage Vref.

The voltage measurement result determination circuit 323 successively outputs output results of the voltage measuring circuit 330 to the terminal for outputting a voltage measurement result 324. Alternatively, the voltage measurement result determination circuit 323 may perform a logical operation on output levels of the voltage measuring circuit 330 and output the result to the terminal for outputting a voltage measurement result 324.

For example, in a case where an OR operation is executed by the voltage measurement result determination circuit 323, when the High level is output in at least one voltage measuring circuit among a plurality of voltage measuring circuits, the High level is output to the terminal for outputting a voltage measurement result 324. In a case where an AND operation is executed by the voltage measurement result determination circuit 323, when the Low level is indicated in at least one voltage measuring circuit among the plurality of voltage measuring circuits, the Low level is output to the terminal for outputting a voltage measurement result 324.

An inspection method for the touch panel control substrate 20 that includes the touch panel controller 300 of the present embodiment is similar to the inspection method described in Embodiment 1, and it is possible to execute, without connecting the touch panel main body 10, inspection for “mounting failure (open circuit failure, short circuit failure)” that is caused in the manufacturing process of the touch panel control substrate.

Although the touch panel controller 100 of Embodiment 1 includes the plurality of voltage measuring circuits and the plurality of sense line drive circuits, in the touch panel controller 300 of the present embodiment, each of the number of voltage measuring circuits and the number of sense line drive circuits is reduced to one. Accordingly, circuit scale of the touch panel controller 300 is reduced, and it is therefore possible to reduce a chip size, thus making it possible to reduce costs of the touch panel controller 300 and the touch panel control substrate 20.

### Embodiment 4

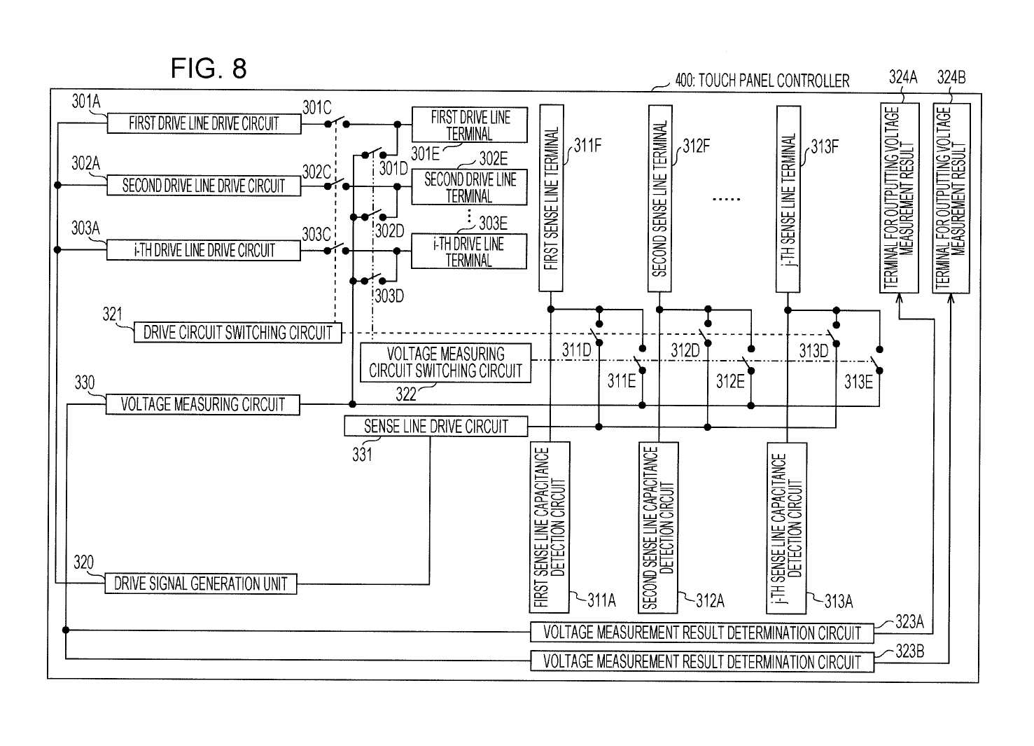

Another embodiment of the invention will be described on the basis of FIG. 8. Note that, for convenience of description, the same reference signs are assigned to members having the same functions as those of the members described in the aforementioned embodiments, and description thereof will be omitted.

FIG. 8 is a block diagram illustrating a schematic configuration of a touch panel controller of the present embodiment.

In a touch panel controller 400, the voltage measurement result determination circuit and the terminal for outputting a voltage measurement result are changed from those of the configuration of the touch panel controller 300 in Embodiment 3, which is illustrated in FIG. 7. The touch panel controller 400 includes two voltage measurement result determination circuits 323A and 323B and two terminals for outputting a voltage measurement result 324A and 324B.

The voltage measurement result determination circuit 323A (first operation unit) executes an OR operation for a plurality of voltage measurement results, and outputs an operation result to the terminal for outputting a voltage measurement result 324A. The voltage measurement result determination circuit 323B (second operation unit) executes an AND operation for the plurality of voltage measurement results, and outputs an operation result to the terminal for outputting a voltage measurement result 324B.

In a case where short circuit failure is caused, at least one of the plurality of voltage measuring circuits outputs a signal of the High level. When the OR operation is executed by the voltage measurement result determination circuit 323A, a signal of the High level is output to the terminal for outputting a voltage measurement result 324A.

In a case where disconnection failure (open circuit failure) is caused, at least one of the plurality of voltage measuring circuits outputs a signal of the Low level. When the AND operation is executed by the voltage measurement result determination circuit 323B, a signal of the Low level is output to the terminal for outputting a voltage measurement result 324B.

Accordingly, in a case where a signal of the High level is output to the terminal for outputting a voltage measurement result 324A, it is possible to judge that short circuit failure is caused, and, in a case where a signal of the Low level is output to the terminal for outputting a voltage measurement result 324B, it is possible to judge that disconnection failure (open circuit failure) is caused.

The touch panel controller 300 of Embodiment 3 includes only one voltage measurement result determination circuit, and is therefore able to execute inspection for only either of short circuit failure and disconnection failure (open circuit failure). On the other hand, the touch panel controller 400 of the present embodiment includes the plurality of voltage measurement result determination circuits and the plurality of terminals for outputting a voltage measurement result so as to be able to execute inspection for both of short circuit failure and disconnection failure (open circuit failure).

Thus, it is possible to execute inspection for failure of both of short circuit failure and disconnection failure (open circuit failure), so that quality of the touch panel control substrate is improved.

Moreover, in the touch panel controller 400, each of the number of voltage measuring circuits and the number of sense line drive circuits is reduced to one. Accordingly, circuit scale of the touch panel controller 400 is reduced, and it is therefore possible to reduce a chip size, thus making it possible to reduce costs of the touch panel controller 400 and the touch panel control substrate 20.

### Embodiment 5

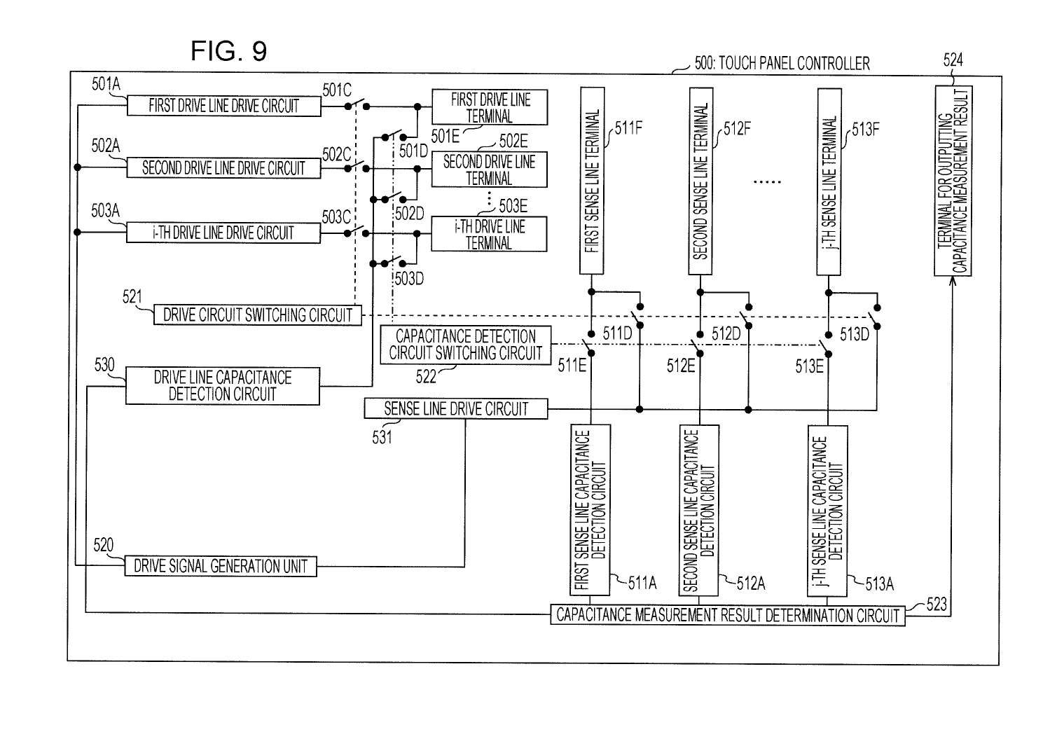

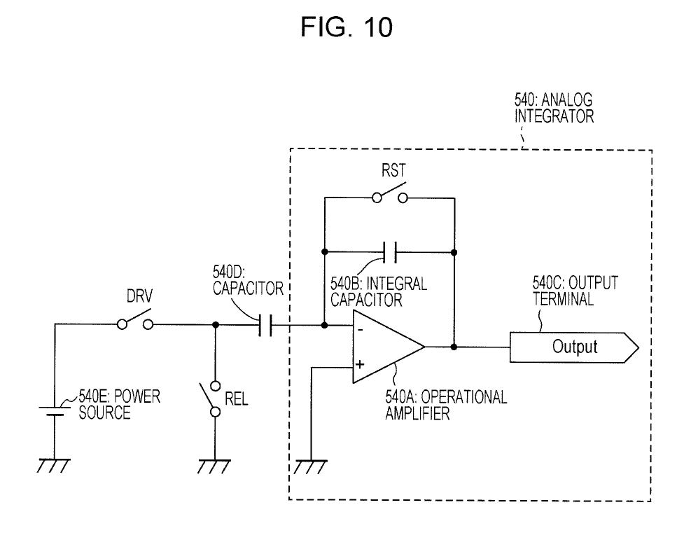

Another embodiment of the invention will be described on the basis of FIG. 9 and FIG. 10. Note that, for convenience of description, the same reference signs are assigned to members having the same functions as those of the members described in the aforementioned embodiments, and description thereof will be omitted.

FIG. 9 is a block diagram illustrating a schematic configuration of a touch panel controller of the present embodiment. A touch panel controller 500 includes i drive line terminals 501E, 502E, and 503E, j sense line terminals 511F, 512F, and 513F, and a terminal for outputting a capacitance measurement result 524.

Switches 501C, 502C, and 503C that switch connection between the drive line terminals and drive line drive circuits 501A, 502A, and 503A and switches 501D, 502D, and 503D that switch connection between the drive line terminals and a drive line capacitance detection circuit 530 (electrostatic capacitance measuring unit) are connected to the drive line terminals 501E, 502E, and 503E, respectively.

Switches 511D, 512D, and 513D that switch connection between the sense line terminals and a sense line drive circuit 531 and switches 511E, 512E, and 513E that switch connection between the sense line terminals and sense line capacitance detection circuits 511A, 512A, and 513A (electrostatic capacitance measuring unit) are connected to the sense line terminals 511F, 512F, and 513F, respectively.

A drive circuit switching circuit 521 is connected to the switches 501C, 502C, and 503C that switch the connection between the drive line terminals and the drive line drive circuits and the switches 511D, 512D, and 513D that switch the connection between the sense line terminals and the sense line drive circuit.

A drive signal generation unit 520 is connected to the drive line drive circuits 501A, 502A, and 503A and the sense line drive circuit 531.

A capacitance detection circuit switching circuit 522 is connected to the switches 501D, 502D, and 503D that switch the connection between the drive line terminals and the drive line capacitance detection circuit and the switches 511E, 512E, and 513E that switch the connection between the sense line terminals and the sense line capacitance detection circuits.

A capacitance measurement result determination circuit 523 is connected to the drive line capacitance detection circuit 530 and the sense line capacitance detection circuits 511A, 512A, and 513A. A terminal for outputting a capacitance measurement result 524 is connected to the capacitance measurement result determination circuit 523.

It is also possible to use the same circuit as each of the drive line drive circuits 501A, 502A, and 503A for the sense line drive circuit 531. The inverter circuit 130, as illustrated in FIG. 4, which is formed of a PMOS transistor and an NMOS transistor may be used as each of these drive circuits.

In the inverter circuit 130, when a signal of the Low level is input to the input terminal 130A, a signal of the High level is output to the output terminal 130B, and, when a signal of the High level is input to the input terminal 130A, a signal of the Low level is output to the output terminal 130B.

FIG. 10 is a view illustrating a configuration and an operation of an analog integrator as an example of the capacitance detection circuit.

An analog integrator 540 as illustrated in FIG. 10 may be used as the drive line capacitance detection circuit 530. Similarly, the analog integrator 540 illustrated in FIG. 10 may be used as each of the sense line capacitance detection circuits 511A, 512A, and 513A.

The analog integrator 540 has an operational amplifier 540A one input of which is connected to a measurement target capacitor 540D having a capacitance value Cx and the other input of which is connected to GND. An integral capacitor 540B having a capacitance Cint and a reset switch RST are arranged between an output of the operational amplifier 540A and the one input of the operational amplifier 540A so as to be in parallel with each other.

In a state where the touch panel main body 10 is not connected to the touch panel control substrate 20, the measurement target capacitor 540D corresponds to a parasitic capacitance formed in wiring (wiring connected to the drive line terminals and the sense line terminals of the touch panel controller) on the touch panel control substrate 20.

As described below, in the capacitance detection circuit, as the capacitance value Cx of the measurement target capacitor 540D is larger, detection accuracy becomes more excellent. Accordingly, it is desired that inspection is executed in a state where the touch panel main body 10 is connected to the touch panel control substrate 20.

An operation of the analog integrator 540 will be described with the use of FIG. 10. The measurement target capacitor 540D is connected to the analog integrator 540. A drive switch DRV and a release switch REL are connected to one terminal of the measurement target capacitor 540D. By turning the drive switch DRV and the release switch REL “on” or “off”, a power source 540E (VDD) or GND is connected to the measurement target capacitor 540D.

A change between the High level and the Low level of a level of a signal which is supplied to a drive line of the touch panel main body 10 by using the drive circuit of the touch panel controller 500 corresponds to “on” or “off” of the two switches DRV and REL. In a case where the High level and the Low level of a level of a signal which is supplied to a drive line are set to be VDD and GND, respectively, it is equivalent to connecting the power source 540E or GND to the measurement target capacitor 540D.

First, the drive switch DRV and the reset switch RST are turned “on”, and the release switch REL is turned “off”. Since a gain of the operational amplifier is large and a virtual short circuit is generated, an output voltage Vout of the operational amplifier 540A becomes equal to a GND level (0 V). A voltage between terminals of the measurement target capacitor 540D becomes VDD, and a charge of Qx=Cx*VDD is accumulated.

Next, the drive switch DRV and the reset switch RST are turned “off”, and the release switch REL is turned “on”. Since the gain of the operational amplifier is large and the virtual short circuit is generated, a voltage of a connecting point of the measurement target capacitor 540D and the integral capacitor 540B becomes GND. When it is set that the output voltage of the operational amplifier 540A is Vout, a voltage between terminals of the integral capacitor 540B becomes Vout, and a charge of Qint=Cint*Vout is accumulated. Since Qint is equal to Qx described above, Cint*Vout=Cx*VDD is satisfied.

Thus, Vout=(Cx/Cint)*VDD and Cx=(Vout/VDD)*Cint are provided. Since VDD and Cint are known, it is possible to calculate Cx from the output voltage Vout of the operational amplifier 540A.

### <Inspection Method>

A method for executing, without connecting the touch panel main body 10, inspection method for “mounting failure (open circuit failure, short circuit failure)” that is caused in the manufacturing process of the touch panel control substrate will be described below.

By successively switching the switches 501C, 502C, 503C, 511D, 512D, and 513D with the use of the drive circuit switching circuit 521, a signal of the High level is output from one of the plurality of drive line terminals and the plurality of sense line terminals. Then, by successively switching the switches 501D, 502D, 503D, 511E, 512E, and 513E with the use of the capacitance detection circuit switching circuit 522, capacitances of the plurality of drive line terminals and the plurality of sense line terminals are measured. At this time, control is performed so that a switch that connects a terminal outputting a signal of the High level and a capacitance detection circuit of the terminal does not perform connection.

In a case of executing inspection for the “mounting failure (open circuit failure, short circuit failure)” that is caused in the manufacturing process of the touch panel control substrate, it is not always necessary to know an accurate capacitance value, and, in some cases, it is sufficient that only a magnitude relation with a capacitance value serving as a criterion of quality determination is known. When the capacitance value serving as the criterion of the quality determination is Ccri, Vcri=(Ccri/Cint)*VDD, which is a voltage conversion value, and the output voltage Vout of the operational amplifier 540A are compared. As a result of the comparison of Vcri and the output voltage Vout, in a case of Vout>Vcri, Cx>Ccri is satisfied, and, in a case of Vout<Vcri, Cx<Cri is satisfied. In this manner, it is possible to perform the quality determination on the basis of the output voltage Vout of the operational amplifier 540A.

### (Short Circuit Failure)

In a case where the touch panel control substrate 20 has short circuit failure, the capacitance value Cx (electrostatic capacitance value) becomes large. When the capacitance value Cx exceeds a capacitance value Cshort that serves as a criterion with which short circuit failure is judged, a signal of the High level is to be output from the capacitance detection circuit (electrostatic capacitance measurement result outputting step).

The output of the capacitance detection circuit is output to the terminal for outputting a capacitance measurement result 524 via the capacitance measurement result determination circuit 523. When an OR operation is executed by the capacitance measurement result determination circuit 523, the High level is output to the terminal for outputting a capacitance measurement result 524.

As above, in a case where short circuit failure is caused, the High level is output to the terminal for outputting a capacitance measurement result 524.

### (Disconnection Failure)

In a case where the touch panel control substrate 20 has disconnection failure (open circuit failure), the capacitance value Cx becomes small. When the capacitance value Cx is smaller than a capacitance value Copen that serves as a criterion with which disconnection failure (open circuit failure) is judged, a signal of the Low level is to be output from the capacitance detection circuit.

The output of the capacitance detection circuit is output to the terminal for outputting a capacitance measurement result 524 via the capacitance measurement result determination circuit 523. When an AND operation is executed by the capacitance measurement result determination circuit 523, the Low level is output to the terminal for outputting a capacitance measurement result 524.

As above, in a case where disconnection failure (open circuit failure) is caused, the Low level is output to the terminal for outputting a capacitance measurement result 524.

### Embodiment 6

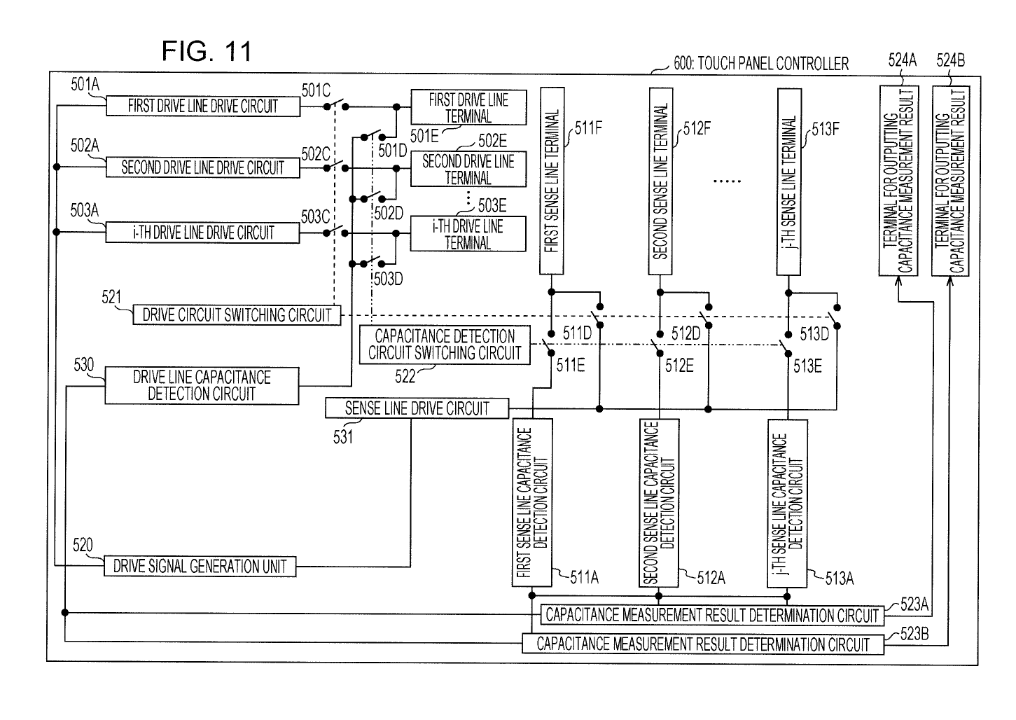

Another embodiment of the invention will be described on the basis of FIG. 11. Note that, for convenience of description, the same reference signs are assigned to members having the same functions as those of the members described in the aforementioned embodiments, and description thereof will be omitted.

FIG. 11 is a block diagram illustrating a schematic configuration of a touch panel controller of the present embodiment.

In a touch panel controller 600, the capacitance measurement result determination circuit and the terminal for outputting a capacitance measurement result are changed from those of the configuration of the touch panel controller 500 in Embodiment 5, which is illustrated in FIG. 9. The touch panel controller 600 includes two capacitance measurement result determination circuits 523A and 523B and two terminals for outputting a capacitance measurement result 524A and 524B.

The capacitance measurement result determination circuit 523A (first operation unit) executes an OR operation for a plurality of capacitance measurement results, and outputs an operation result to the terminal for outputting a capacitance measurement result 524A. The capacitance measurement result determination circuit 523B (second operation unit) executes an AND operation for the plurality of capacitance measurement results, and outputs an operation result to the terminal for outputting a capacitance measurement result 524B.

In a case where short circuit failure is caused, at least one of the plurality of capacitance detection circuits outputs a signal of the High level. When the OR operation is executed by the capacitance measurement result determination circuit 523A, a signal of the High level is output to the terminal for outputting a capacitance measurement result 524A.

In a case where disconnection failure (open circuit failure) is caused, at least one of the plurality of capacitance detection circuits outputs a signal of the Low level. When the AND operation is executed by the capacitance measurement result determination circuit 523B, a signal of the Low level is output to the terminal for outputting a capacitance measurement result 524B.

Accordingly, in a case where a signal of the High level is output to the terminal for outputting a capacitance measurement result 524A, it is possible to judge that short circuit failure is caused, and, in a case where a signal of the Low level is output to the terminal for outputting a capacitance measurement result 524B, it is possible to judge that disconnection failure (open circuit failure) is caused.

The touch panel controller 500 of Embodiment 5 includes only one capacitance measurement result determination circuit, and is therefore able to execute inspection for only either of short circuit failure and disconnection failure (open circuit failure). On the other hand, the touch panel controller 600 of the present embodiment includes the plurality of capacitance measurement result determination circuits and the plurality of terminals for outputting a capacitance measurement result so as to be able to execute inspection for both of short circuit failure and disconnection failure (open circuit failure).

Thus, it is possible to execute inspection for failure of both of short circuit failure and disconnection failure (open circuit failure), so that quality of the touch panel control substrate is improved.

### Embodiment 7

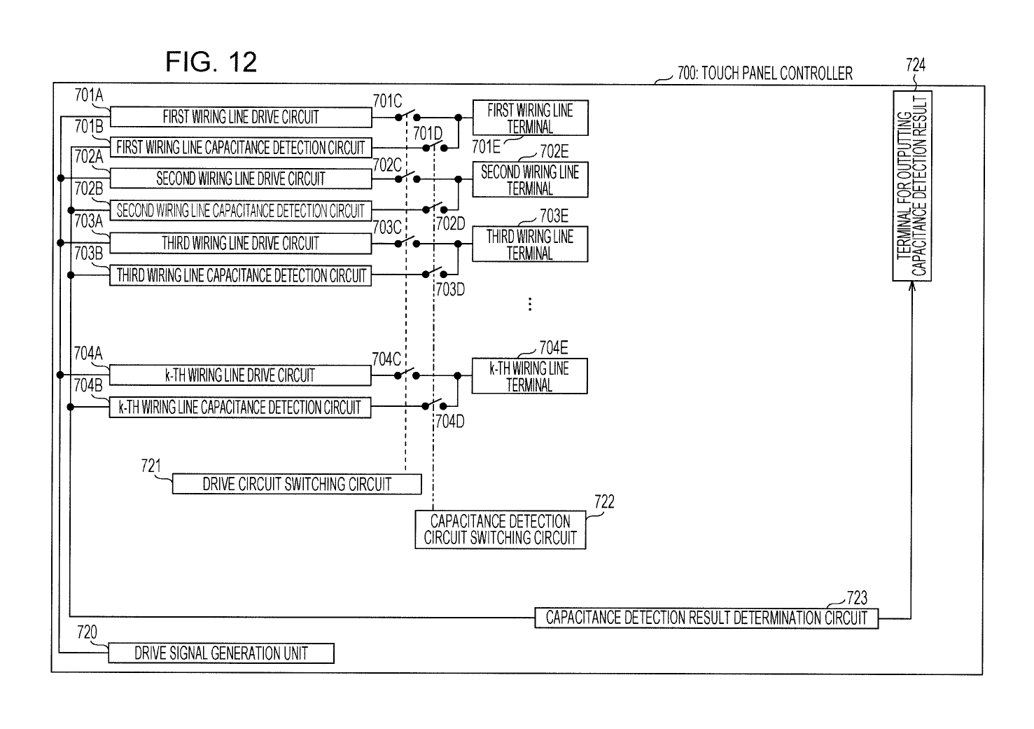

Another embodiment of the invention will be described on the basis of FIG. 12. Note that, for convenience of description, the same reference signs are assigned to members having the same functions as those of the members described in the aforementioned embodiments, and description thereof will be omitted.

FIG. 12 is a block diagram illustrating a schematic configuration of a touch panel controller of the present embodiment.

A touch panel controller 700 includes k wiring line terminals 701E, 702E, 703E, and 704E, and a terminal for outputting a capacitance detection result 724.

Switches 701C, 702C, 703C, and 704C that switch connection between the wiring line terminals and wiring line drive circuits 701A, 702A, 703A, and 704A and switches 701D, 702D, 703D, and 704D that switch connection between the wiring line terminals and wiring line capacitance detection circuits 701B, 702B, 703B, and 704B (electrostatic capacitance measuring unit) are connected to the wiring line terminals 701E, 702E, 703E, and 704E, respectively.

A drive circuit switching circuit 721 is connected to the switches 701C, 702C, 703C, and 704C that switch the connection between the wiring line terminals and the drive circuits. A drive signal generation unit 720 is connected to the wiring line drive circuits 701A, 702A, 703A, and 704A.

A capacitance detection circuit switching circuit 722 is connected to the switches 701D, 702D, 703D, and 704D that switch the connection between the wiring line terminals and capacitance detection circuits.

A capacitance detection result determination circuit 723 is connected to the wiring line capacitance detection circuits 701B, 702B, 703B, and 704B, and the terminal for outputting a capacitance detection result 724 is connected to the capacitance detection result determination circuit 723.

With the aforementioned configuration, by switching the switches 701C, 702C, 703C, 704C, 701D, 702D, 703D, and 704D of the touch panel controller 700, it is possible to switch, between the drive lines and the sense lines, a connection destination of each of the k wiring line terminals 701E, 702E, 703E, and 704E in the touch panel main body 10. That is, it is possible to use each of the k wiring line terminals 701E, 702E, 703E, and 704E as a drive line terminal and also as a sense line terminal.

In this manner, when being connected to the touch panel main body 10, the touch panel controller 700 is able to operate with the drive lines and the sense lines of the touch sensor sheet 11 switched, so that more accurate touch recognition is enabled.

### <Inspection Method>

A method for executing, without connecting the touch panel main body 10, inspection for “mounting failure (open circuit failure, short circuit failure)” that is caused in the manufacturing process of the touch panel control substrate will be described below.

By successively switching the switches 701C, 702C, 703C, and 704C with the use of the drive circuit switching circuit 721, a signal of the High level is output from one of the plurality of wiring line terminals. Then, by successively switching the switches 701D, 702D, 703D, and 704D with the use of the capacitance detection circuit switching circuit 722, capacitances of the plurality of wiring line terminals are measured. At this time, control is performed so that a switch that connects a terminal outputting a signal of the High level and a capacitance detection circuit of the terminal does not perform connection.

### (Short Circuit Failure)

In a case where the touch panel control substrate 20 has short circuit failure, a capacitance value to be detected by a capacitance detection circuit becomes large. When the detected capacitance value exceeds the capacitance value Cshort that serves as the criterion with which short circuit failure is judged, a signal of the High level is to be output from the capacitance detection circuit.

The output of the capacitance detection circuit is output to the terminal for outputting a capacitance detection result 724 via the capacitance detection result determination circuit 723. When an OR operation is executed by the capacitance detection result determination circuit 723, the High level is output to the terminal for outputting a capacitance detection result 724.

As above, in a case where short circuit failure is caused, the High level is output to the terminal for outputting a capacitance detection result 724.

### (Disconnection Failure)

In a case where the touch panel control substrate 20 has disconnection failure (open circuit failure), a capacitance value to be detected by a capacitance detection circuit becomes small. When the detected capacitance value is smaller than the capacitance value Copen that serves as a criterion with which disconnection failure (open circuit failure) is judged, a signal of the Low level is to be output from the capacitance detection circuit.

The output of the capacitance detection circuit is output to the terminal for outputting a capacitance detection result 724 via the capacitance detection result determination circuit 723. When an AND operation is executed by the capacitance detection result determination circuit 723, the Low level is output to the terminal for outputting a capacitance detection result 724.

As above, in a case where disconnection failure (open circuit failure) is caused, the Low level is output to the terminal for outputting a capacitance detection result 724.

As described above, the touch panel controller 700 includes the wiring line terminals, the wiring line drive circuits, the wiring line capacitance detection circuits, the switches that switch the connection between the wiring line terminals and the wiring line drive circuits, the switches that switch the connection between the wiring line terminals and the wiring line capacitance detection circuits, the drive circuit switching circuit, the drive signal generation unit, the capacitance detection circuit switching circuit, the capacitance detection result determination circuit, and the terminal for outputting a capacitance detection result.

The touch panel controller 700 incorporates a test function that a signal for drive is successively output to the wiring line terminals and capacitance values of terminals other than the terminal for which output is performed are measured to output a measurement result on the basis of capacitance value measurement results.

By incorporating the aforementioned test function, it is possible to execute, without connecting the touch panel main body, inspection for “mounting failure (open circuit failure, short circuit failure)” that is caused in the manufacturing process of the touch panel control substrate.

### Embodiment 8

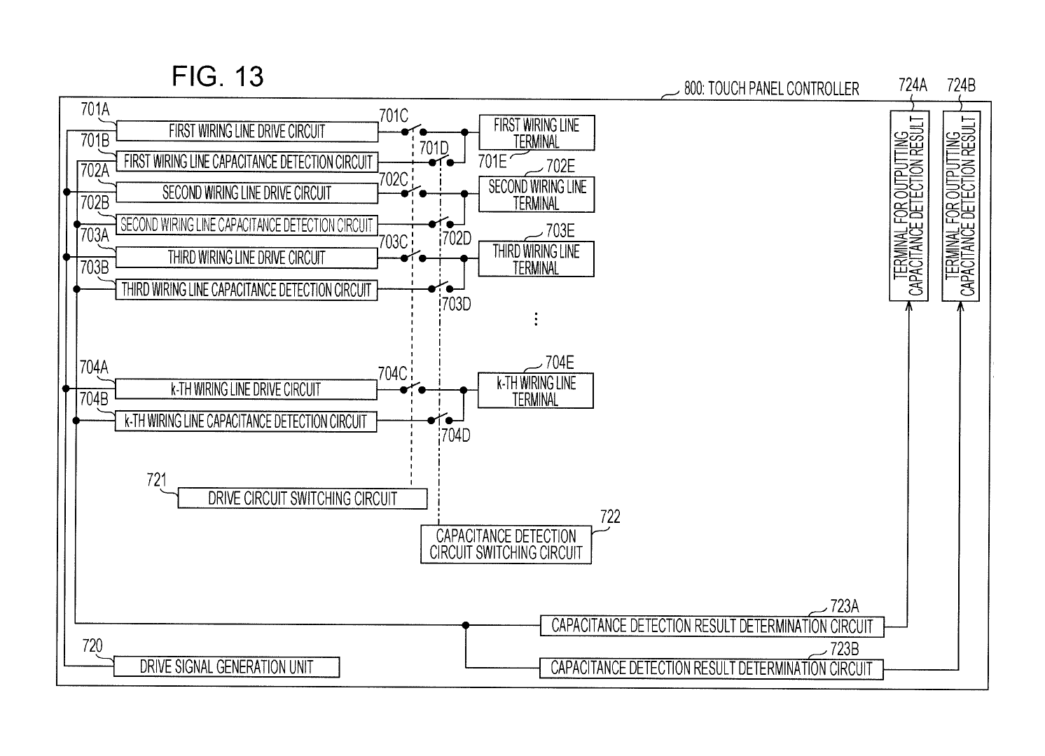

Another embodiment of the invention will be described on the basis of FIG. 13. Note that, for convenience of description, the same reference signs are assigned to members having the same functions as those of the members described in the aforementioned embodiments, and description thereof will be omitted.

FIG. 13 is a block diagram illustrating a schematic configuration of a touch panel controller of the present embodiment.

In a touch panel controller 800, the capacitance detection result determination circuit and the terminal for outputting a capacitance detection result are changed from those of the configuration of the touch panel controller 700 in Embodiment 7, which is illustrated in FIG. 12. The touch panel controller 800 includes two capacitance detection result determination circuits 723A and 723B and two terminals for outputting a capacitance detection result 724A and 724B.

The capacitance measurement result determination circuit 723A (first operation unit) executes an OR operation for a plurality of capacitance measurement results, and outputs an operation result to the terminal for outputting a capacitance measurement result 724A. The capacitance measurement result determination circuit 723B (second operation unit) executes an AND operation for the plurality of capacitance measurement results, and outputs an operation result to the terminal for outputting a capacitance measurement result 724B.

In a case where short circuit failure is caused, at least one of the plurality of capacitance detection circuits outputs a signal of the High level. When the OR operation is executed by the capacitance measurement result determination circuit 723A, a signal of the High level is output to the terminal for outputting a capacitance measurement result 724A.

In a case where disconnection failure (open circuit failure) is caused, at least one of the plurality of capacitance detection circuits outputs a signal of the Low level. When the AND operation is executed by the capacitance measurement result determination circuit 723B, a signal of the Low level is output to the terminal for outputting a capacitance measurement result 724B.

Accordingly, in a case where a signal of the High level is output to the terminal for outputting a capacitance measurement result 724A, it is possible to judge that short circuit failure is caused, and, in a case where a signal of the Low level is output to the terminal for outputting a capacitance measurement result 724B, it is possible to judge that disconnection failure (open circuit failure) is caused.

The touch panel controller 700 of Embodiment 7 includes only one capacitance measurement result determination circuit, and is therefore able to execute inspection for only either of short circuit failure and disconnection failure (open circuit failure). On the other hand, the touch panel controller 800 of the present embodiment includes the plurality of capacitance measurement result determination circuits and the plurality of terminals for outputting a capacitance measurement result so as to be able to execute inspection for both of short circuit failure and disconnection failure (open circuit failure).

Thus, it is possible to execute inspection for failure of both of short circuit failure and disconnection failure (open circuit failure), so that quality of the touch panel control substrate is improved.

### Embodiment 9

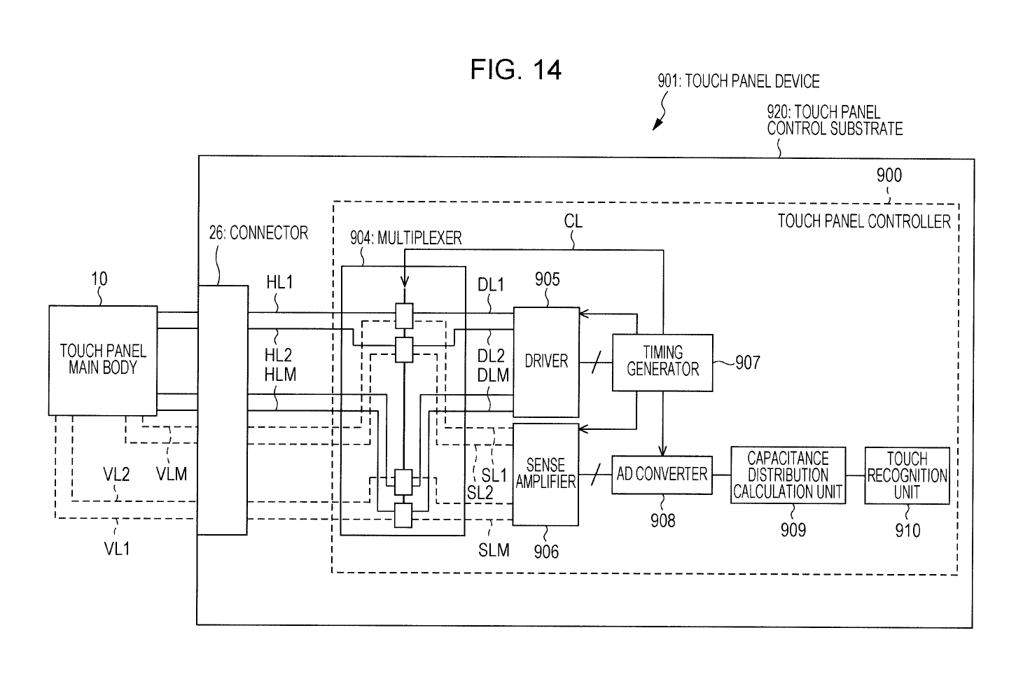

Another embodiment of the invention will be described on the basis of FIG. 14 to FIG. 17. Note that, for convenience of description, the same reference signs are assigned to members having the same functions as those of the members described in the aforementioned embodiments, and description thereof will be omitted.

FIG. 14 is a block diagram illustrating a schematic configuration of a touch panel device of the present embodiment.

A touch panel device 901 includes the touch panel main body 10 and a touch panel control substrate 920.

The touch panel control substrate 920 includes a touch panel controller 900 and a connector 26.

The touch panel controller 900 includes a multiplexer 904, a driver 905, a sense amplifier 906, a timing generator 907, an AD converter 908, a capacitance distribution calculation unit 909, and a touch recognition unit 910.

The touch panel controller 900 is constituted by one integrated circuit and mounted on a substrate. Signal lines HL1, HL2, . . . , and HLM and VL1, VL2, . . . , and VLM of the touch panel controller 900 are connected to the connector 26 by wiring on the substrate.

The touch panel main body 10 and the connector 26 is connected with the use of a connection cable, and each of the signal lines HL1, HL2, . . . , and HLM are connected to an electrode of the touch panel main body 10, which extends in a horizontal direction, and each of the signal lines VL1, VL2, . . . , VLM are connected to an electrode of the touch panel main body 10, which extends in a vertical direction.

The driver 905 applies a voltage to drive lines DL1 to DLM on the basis of a coded sequence. The sense amplifier 906 reads linear sums of charges, each of which corresponds to each electrostatic capacitance, through sense lines SL1 to SLM, and supplies the linear sums to the AD converter 908. Note that, a circuit similar to each of the wiring line drive circuits 701A, 702A, 703A, and 704A of Embodiment 7 may be used as the driver 905, and a circuit similar to each of the wiring line capacitance detection circuits 701B, 702B, 703B, and 704B of Embodiment 7 may be used as the sense amplifier 906.

The multiplexer 904 performs switching between a first connection state where the signal lines HL1 to HLM are connected to the drive lines DL1 to DLM of the driver 905 and the signal lines VL1 to VLM are connected to the sense lines SL1 to SLM of the sense amplifier 906 and a second connection state where the signal lines HL1 to HLM are connected to the sense lines SL1 to SLM of the sense amplifier 906 and the signal lines VL1 to VLM are connected to the drive lines DL1 to DLM of the driver 905.

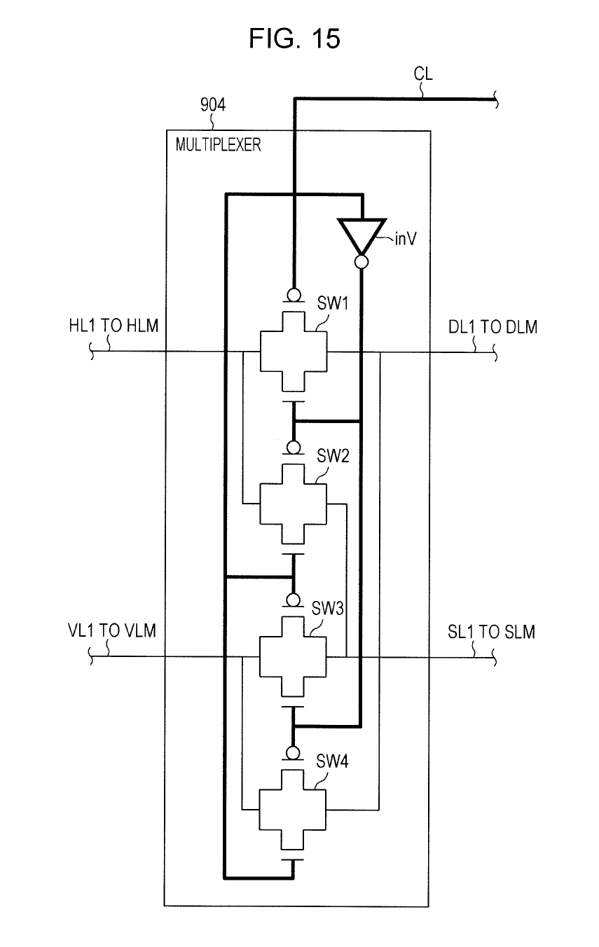

FIG. 15 is a circuit diagram illustrating a configuration of the multiplexer. The multiplexer 904 has four CMOS switches SW1 to SW4 which are connected in series. A control line CL from the timing generator 907 is connected to an end of the CMOS switch SW1, which is on a side opposite to the COMS switch SW2, between the CMOS switch SW2 and the CMOS switch SW3, to an end of the CMOS switch SW4, which is on a side opposite to the COMS switch SW3, and to an input of an inverter inv. An output of the inverter inv is connected between the CMOS switch SW1 and the CMOS switch SW2 and between the CMOS switch SW3 and the CMOS switch SW4. The signal lines HL1 to HLM are connected to the CMOS switches SW1 and SW2. The signal lines VL1 to VLM are connected to the CMOS switches SW3 and SW4. The drive lines DL1 to DLM are connected to the CMOS switches SW1 and SW4. The sense lines SL1 to SLM are connected to the CMOS switches SW2 and SW3.

When a signal of the control line CL is set to be Low, the signal lines HL1 to HLM are connected to the drive lines DL1 to DLM and the signal lines VL1 to VLM are connected to the sense lines SL1 to SLM. When the signal of the control line CL is set to be High, the signal lines HL1 to HLM are connected to the sense lines SL1 to SLM and the signal lines VL1 to VLM are connected to the drive lines DL1 to DLM.

The AD converter 908 performs AD conversion for the linear sums of charges each corresponding to each of the electrostatic capacitances, which are read through the sense lines SL1 to SLM, to supply the resultants to the capacitance distribution calculation unit 909.

Based on the linear sums of the charges each corresponding to each of the electrostatic capacitances, which are supplied from the AD converter 908, and the coded sequence, the capacitance distribution calculation unit 909 calculates distribution of the electrostatic capacitances on the touch panel main body 10 to supply the resultant to the touch recognition unit 910. The touch recognition unit 910 recognizes a touched position on the touch panel main body 10 on the basis of the distribution of the electrostatic capacitances, which is supplied from the capacitance distribution calculation unit 909.

The timing generator 907 generates a signal defining an operation of the driver 905, a signal defining an operation of the sense amplifier 906 and a signal defining an operation of the AD converter 908 to supply them to the driver 905, the sense amplifier 906 and the AD converter 908, respectively.

### <Inspection Method>

A method for executing, without connecting the touch panel main body 10, inspection method for “mounting failure (open circuit failure, short circuit failure)” that is caused in the manufacturing process of the touch panel control substrate will be described below.

In description below, it is set that a state where the signal lines HL1 to HLM are connected to the drive lines DL1 to DLM of the driver 905 and the signal lines VL1 to VLM are connected to the sense lines SL1 to SLM of the sense amplifier 906 is the first connection state and a state where the signal lines HL1 to HLM are connected to the sense lines SL1 to SLM of the sense amplifier 906 and the signal lines VL1 to VLM are connected to the drive lines DL1 to DLM of the driver 905 is the second connection state.

### (Short Circuit Failure)

### (Detection of Short Circuit Failure in Signal Lines HL1 to HLM)

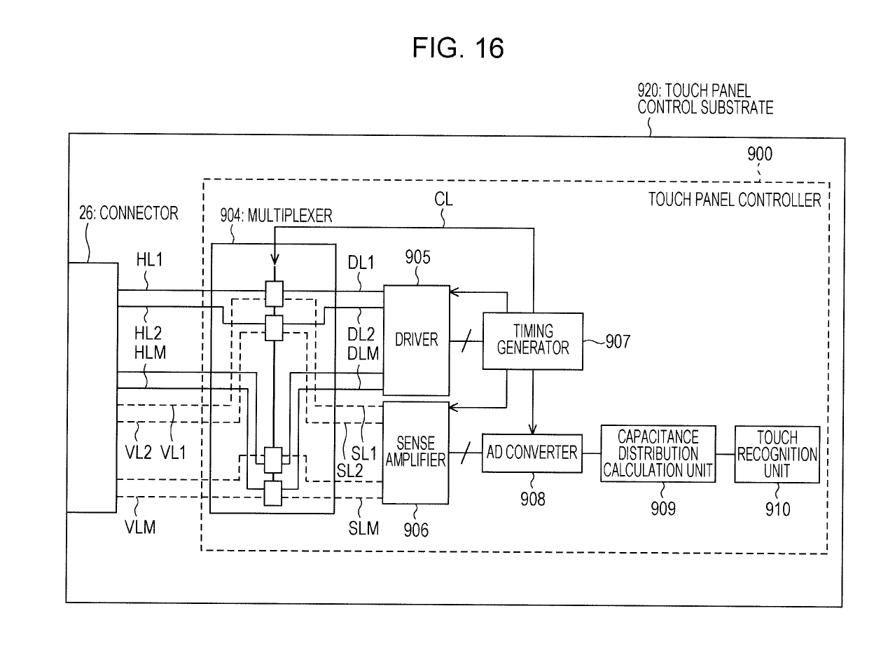

FIG. 16 is a block diagram illustrating a schematic configuration of the touch panel control substrate at a time of inspection for short circuit failure.

First, in the first connection state, drive signals are output to the drive lines DL1 to DLM simultaneously. At this time, when a drive signal is output to the respective drive lines DL1 to DLM each corresponding to each of the signal lines HL1 to HLM which are arrayed in rows, mutually different drive signals are supplied to adjacent drive lines among the drive lines DL1 to DLM.

For example, among the drive lines DL1 to DLM, a drive signal of “H” is supplied to the drive lines DL1, DL3, DL5, . . . , and a drive signal of “L” is supplied to the drive lines DL2, DL4, DL6, . . . . Thereby, mutually different electrostatic capacitances are held in adjacent signal lines among the signal lines HL1 to HLM (drive lines DL1 to DLM).

Next, the first connection state is switched to the second connection state, and the electrostatic capacitances of the signal lines HL1 to HLM are read by the sense amplifier 906. At this time, in a case where short circuit failure is caused between the signal lines HL1 to HLM, the electrostatic capacitances (in a case of being converted into voltages, voltage levels) of the signal lines HL1 to HLM change, so that it is possible to detect the short circuit failure in the signal lines HL1 to HLM by comparing the electrostatic capacitances which are to be held originally and the read electrostatic capacitances of the signal lines HL1 to HLM.

Moreover, by changing a pattern of the drive signals to be supplied to the drive lines DL1 to DLM and performing measurement again, it is possible to improve accuracy of detecting short circuit failure.

Note that, states of the signal lines HL1 to HLM are held with capacitors of wiring lines or the like, but, in a case where holding time is short, holding capacitors may be connected with the use of connector parts.

### (Detection of Short Circuit Failure in Signal Lines VL1 to VLM)

Similarly to a case of detecting short circuit failure in the signal lines HL1 to HLM, after drive signals are output to the drive lines DL1 to DLM simultaneously in the second connection state, the second connection state is switched to the first connection state, and electrostatic capacitances of the signal lines VL1 to VLM are read by the sense amplifier 906.

Thereby, it is possible to detect short circuit failure in the signal lines VL1 to VLM.

### (Detection of Short Circuit Failure Between Signal Lines HL1 to HLM and Signal Lines VL1 to VLM)

First, in the first connection state, a drive signal of “H” is output to the signal lines HL1 to HLM (first connection terminal group) (first supplying step). Next, in the second connection state, a drive signal of “L” is output to the signal lines VL1 to VLM (second connection terminal group) (second supplying step), and electrostatic capacitances of the signal lines HL1 to HLM are read by the sense amplifier 906.

When short circuit failure is caused between the signal lines HL1 to HLM and the signal lines VL1 to VLM, a signal line among the signal lines HL1 to HLM becomes unable to hold a potential state of “H”. Thus, it is possible to detect the short circuit failure between the signal lines HL1 to HLM and the signal lines VL1 to VLM by comparing the electrostatic capacitances which are to be held originally and the read electrostatic capacitances of the signal lines HL1 to HLM.

Similarly, it is possible to improve accuracy of detecting short circuit failure between the signal lines HL1 to HLM and the signal lines VL1 to VLM by supplying a drive signal of “H” to the signal lines VL1 to VLM and reading electrostatic capacitances of the signal lines VL1 to VLM by the sense amplifier 906.

### (Disconnection Failure)

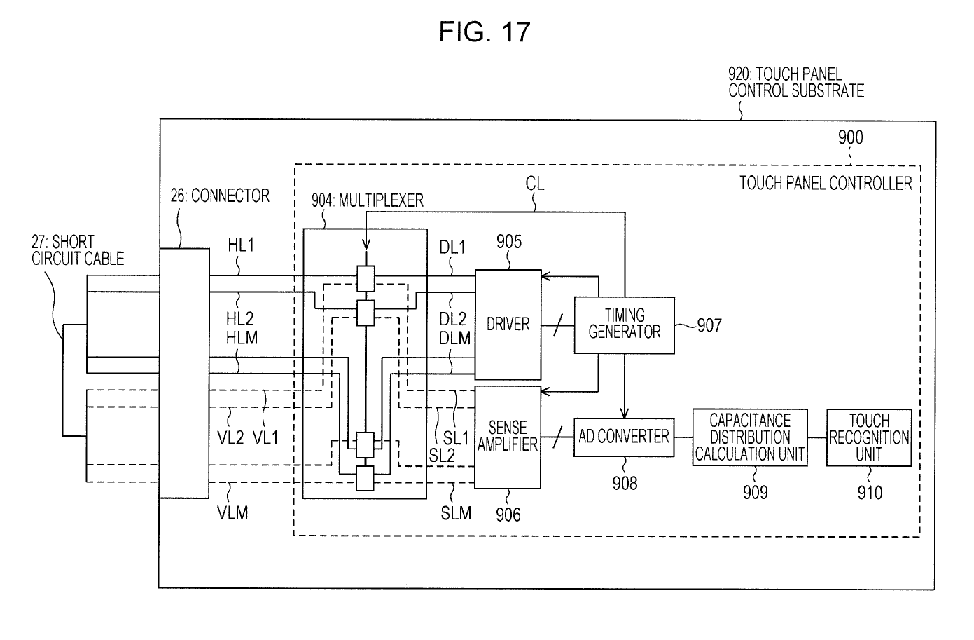

FIG. 17 is a block diagram illustrating a schematic configuration of the touch panel control substrate at a time of inspection for disconnection failure.

In a case of inspection for disconnection failure, as illustrated in FIG. 17, the signal lines HL1 to HLM and the signal lines VL1 to VLM are brought into a short circuit state on purpose by connecting a short circuit cable 27 to the connector 26 on the outside of the touch panel control substrate 20.

Next, in the first connection state, the same drive signal is supplied to the signal lines HL1 to HLM, and electrostatic capacitances of the signal lines VL1 to VLM are read by the sense amplifier 906.

In a case where open circuit failure is caused in the signal lines VL1 to VLM, electrostatic capacitances corresponding to the drive signal supplied to the signal lines HL1 to HLM are not held by the signal lines VL1 to VLM, so that it is possible to detect the open circuit failure of the signal lines VL1 to VLM by comparing the electrostatic capacitances which are to be held originally and the read electrostatic capacitances of the signal lines VL1 to VLM.

Next, in the second connection state, the same drive signal is supplied to the signal lines VL1 to VLM, and electrostatic capacitances of the signal lines HL1 to HLM are read by the sense amplifier 906.

In a case where open circuit failure is caused in the signal lines HL1 to HLM, electrostatic capacitances corresponding to the drive signal supplied to the signal lines VL1 to VLM are not held by the signal lines HL1 to HLM, so that it is possible to detect the open circuit failure of the signal lines HL1 to HLM by comparing the electrostatic capacitances which are to be held originally and the read electrostatic capacitances of the signal lines HL1 to HLM.

### <Supplementary Note>

The above-described inspection methods of Embodiments 5 to 9 are inspection methods using a capacitance detection circuit. In the capacitance detection circuit, detection accuracy becomes better, as a capacitance value of a measurement target capacitor is larger. Thus, it is desired that inspection for “mounting failure (open circuit failure, short circuit failure)” that is caused in the manufacturing process of the touch panel control substrate is executed by connecting the touch panel main body 10 to the touch panel control substrate 20. However, even in a case of connecting the touch panel main body 10, since it is not necessary to touch the touch panel main body 10 during the inspection, compared with a conventional inspection method, there are advantages that inspection time is reduced and an increase in manufacturing costs of the touch panel control substrate 20 is suppressed.

### CONCLUSION

An inspection method for a touch panel control substrate (20) according to an aspect 1 of the invention is an inspection method for a touch panel control substrate including a touch panel controller (100, 200, 300, 400, 500, 600, 700, 800, 900) that supplies, via a connector (23, 24), a drive signal to a plurality of signal lines provided in a touch panel main body (10), including a supplying step of supplying the drive signal to a plurality of connection terminals (the drive line terminal 101E, the sense line terminal 111F, the wiring line terminal 701E) each of which is electrically connected to each of the signal lines via the connector, and a detecting step of detecting, on the basis of each response obtained, in response to the drive signal supplied to a connection terminal among the connection terminals, in connection terminals other than the connection terminal, an electrical connection state between the connection terminal and each of the other connection terminals.

With the aforementioned inspection method, by executing the detecting step, it is possible to detect the electrical connection state of the connection terminal and each of the other connection terminals.

Accordingly, it is possible to detect the electrical connection state of the connection terminal and each of the other connection terminals without connecting the touch panel control substrate to the touch panel main body to drive the touch panel main body, so that it is possible to detect wiring failure, such as short circuit or disconnection of wiring, between each of the connection terminals and the connector.

Thereby, it is possible to simply execute inspection for mounting failure in a mounting process of the touch panel control substrate.

In an inspection method for a touch panel control substrate according to an aspect 2 of the invention, the detecting step may include a voltage measurement result outputting step of outputting, in accordance with a voltage of each of the other connection terminals at a time of supplying the drive signal to the connection terminal, any one of two value signals each of which corresponds to presence or absence of an electrical connection between the connection terminal and each of the other connection terminals, and an operation step of executing an operation for signals each of which corresponds to each of the connection terminals, in the aforementioned aspect 1.

With the aforementioned inspection method, by executing the detecting step, it is possible to detect short circuit between the connection terminal and each of the other connection terminals in accordance with the voltage of each of the other connection terminal.

Moreover, by executing the operation step, it is possible to make a failure determination in a case where wiring failure is caused in any of the connection terminals.

Note that, the detecting step may include an electrostatic capacitance measurement result outputting step of measuring an electrostatic capacitance value of each of the other connection terminals and outputting, on the basis of the electrostatic capacitance value, any one of two value signals each of which corresponds to the presence or absence of an electrical connection between the connection terminal and each of the other connection terminals, and an operation step of executing an operation for signals each of which corresponds to each of the connection terminals.

With the aforementioned inspection method, by executing the detecting step, it is possible to detect short circuit between the connection terminal and each of the other connection terminals in accordance with the electrostatic capacitance value of each of the other connection terminals.

Moreover, by executing the operation step, it is possible to make a failure determination in a case where wiring failure is caused in any of the connection terminals.

Note that, at the operation step, an operation of a logical sum of the signals may be executed.

With the aforementioned inspection method, it is possible to detect short circuit between the connection terminal and each of the other connection terminals and to make a failure determination by a simple method.

Note that, after performing at least one of the supplying step and the detecting step in a state where the connection terminal and each of the other connection terminals are short-circuited on the outside of the touch panel control substrate, an operation of a logical product of the signals may be executed at the operation step.

With the aforementioned inspection method, it is possible to detect disconnection between each of the other connection terminals and the connector and make a failure determination by a simple method.

An inspection method for a touch panel control substrate according to an aspect 3 of the invention is an inspection method for a touch panel control substrate including a touch panel controller that supplies, via a connector, a drive signal to a plurality of signal lines provided in a touch panel main body, including a supplying step of supplying the drive signal to a connection terminal that is electrically connected to the signal lines via the connector, and a detecting step of measuring an electrostatic capacitance value of the connection terminal to which the drive signal is supplied and detecting, on the basis of the electrostatic capacitance value, an electrical connection state between the connection terminal and each of other connection terminals.

With aforementioned inspection method, by measuring the electrostatic capacitance value of the connection terminal to which the drive signal is supplied, it is possible to detect short circuit between the connection terminal and each of the other connection terminals and disconnection between the other connection terminals and the connector from a relation between an electrostatic capacitance value which is to be originally held in accordance with the supplied drive signal and the measured electrostatic capacitance value.

In an inspection method for a touch panel control substrate according to an aspect 4 of the invention, the connection terminals may be arrayed in rows, and at the supplying step, mutually different drive signals may be supplied to the connection terminals that are adjacent to each other, and at the detecting step, on the basis of an electrostatic capacitance value of each of the connection terminals, an electrical connection state between the connection terminal and a connection terminal that is adjacent thereto may be detected, in the aforementioned aspect 3.

With the aforementioned inspection method, since, at the supplying step, mutually different drive signals are supplied to the connection terminals that are adjacent to each other, it is possible to make a correct quality determination on the basis of an electrostatic capacitance value of each of the connection terminals at the detecting step.

In an inspection method for a touch panel control substrate according to an aspect 5 of the invention, the supplying step may include a first supplying step of supplying a first drive signal to a first connection terminal group that is composed of some connection terminals of the plurality of connection terminals, and a second supplying step of supplying a second drive signal that is different from the first drive signal to a second connection terminal group that is composed of other connection terminals of the plurality of connection terminals, and at the detecting step, on the basis of an electrostatic capacitance value of each of the connection terminals included in the first connection terminal group, an electrical connection state between the connection terminal and each of the connection terminals included in the second connection terminal group may be detected, in the aforementioned aspect 3.

With the aforementioned inspection method, at the supplying step, the first drive signal is supplied to the connection terminals included in the first connection terminal group and the second drive signal is supplied to the connection terminals included in the second connection terminal group. Thus, at the detecting step, on the basis of an electrostatic capacitance value of each of the connection terminals included in the first connection terminal group, it is possible to detect an electrical connection state between each of the connection terminals included in the first connection terminal group and each of the connection terminals included in the second connection terminal group and to make a quality determination.

Note that, at least one of the supplying step and the detecting step may be performed in a state where the connection terminal and the different connection terminal are short-circuited on the outside of the touch panel control substrate.

With the aforementioned inspection method, it is possible to detect disconnection failure in the connection terminals and make a quality determination.

A touch panel controller (100, 200, 300, 400, 500, 600, 700, 800, 900) according to an aspect 6 of the invention is a touch panel controller that supplies, via a connector (23, 24), a drive signal to a plurality of signal lines provided in a touch panel main body (10), including a plurality of connection terminals (the drive line terminal 101E, the sense line terminal 111F, the wiring line terminal 701E) each of which is electrically connected to each of the signal lines via the connector, a drive circuit (the drive line drive circuit 101C, the sense line drive circuit 111D, the wiring line drive circuit 701C) that supplies the drive signal to the connection terminals, and a detection unit (the drive line voltage measuring circuit 101B, the sense line voltage measuring circuit 111C, the voltage measuring circuit 330, the drive line capacitance detection circuit 530, the sense line capacitance detection circuit 511A, the wiring line capacitance detection circuit 701B, the voltage measurement result determination circuit 123, the capacitance measurement result determination circuit 523) that detects, on the basis of each response obtained, in response to the drive signal supplied to a connection terminal among the connection terminals, in connection terminals other than the connection terminal, an electrical connection state between the connection terminal and each of the other connection terminals.

With the aforementioned configuration, by including the detection unit, it is possible to detect the electrical connection state between the connection terminal and each of the other connection terminals.

Accordingly, without connecting the touch panel controller to the touch panel main body to drive the touch panel main body, it is possible to detect an electrical connection state between the connection terminal and each of the other connection terminals and to detect wiring failure, such as short circuit or disconnection of wiring, between each of the connection terminals and the connector.

Thereby, it is possible to simply execute inspection for mounting failure in a process of mounting the touch panel controller and the connector on the substrate.

In a touch panel controller according to an aspect 7 of the invention, the detection unit may include a voltage measuring unit (the drive line voltage measuring circuit 101B, the sense line voltage measuring circuit 111C, the voltage measuring circuit 330) that outputs, in accordance with a voltage of each of the other connection terminals at a time of supplying the drive signal to the connection terminal, any one of two value signals each of which corresponds to presence or absence of an electrical connection between the connection terminal and each of the other connection terminals, and an operation unit (the voltage measurement result determination circuit 123, the capacitance measurement result determination circuit 523) that executes an operation for signals each of which corresponds to each of the connection terminals, in the aforementioned aspect 6.

With the aforementioned configuration, it is possible to detect short circuit between the connection terminal and each of the other connection terminals in accordance with a voltage of each of the other connection terminals. Moreover, by short-circuiting the connection terminals on the outside of the touch panel control substrate with the use of a jig or the like, it is possible to detect disconnection between each of the other connection terminals and the connector.

In addition, by executing an operation for the signals each of which corresponds to each of the connection terminals, it is possible to make a failure determination in a case where wiring failure is caused in any of the connection terminals.

In a touch panel controller according to an aspect 8 of the invention, the detection unit may include an electrostatic capacitance measuring unit (the drive line capacitance detection circuit 530, the sense line capacitance detection circuit 511A, the wiring line capacitance detection circuit 701B) that measures an electrostatic capacitance value of each of the other connection terminals and outputs, on the basis of the electrostatic capacitance value, any one of two value signals each of which corresponds to presence or absence of an electrical connection between the connection terminal and each of the other connection terminals, and an operation unit that executes an operation for signals each of which corresponds to each of the connection terminals, in the aforementioned aspect 6.

With the aforementioned configuration, it is possible to detect short circuit between the connection terminal and each of the other connection terminals and disconnection between each of the other connection terminals and the connector in accordance with an electrostatic capacitance value of each of the other connection terminal.

In addition, by executing an operation for the signals each of which corresponds to each of the connection terminals, it is possible to make a failure determination in a case where wiring failure is caused in any of the connection terminals.

Note that, as the operation unit, a first operation unit (the voltage measurement result determination circuit 123A, the capacitance measurement result determination circuit 523A) that executes an operation of a logical sum of the signals and a second operation unit (the voltage measurement result determination circuit 123B, the capacitance measurement result determination circuit 523B) that executes an operation of a logical product of the signals may be provided.

With the aforementioned configuration, it is possible to detect short circuit between the connection terminal and each of the other connection terminals and to make a failure determination, and it is possible to detect disconnection between each of the other connection terminals and the connector and to make a failure determination.

Thereby, it is possible to correctly make a failure determination in a case where wiring failure is caused in any of the connection terminals.

The invention is not limited to each of the embodiments described above, and may be modified in various manners within the scope shown in the claims and an embodiment achieved by appropriately combining technical means disclosed in each of different embodiments is also encompassed in the technical scope of the invention. Further, by combining the technical means disclosed in each of the embodiments, a new technical feature may be formed.

### INDUSTRIAL APPLICABILITY

The invention is able to be used for inspection in a manufacturing process of a touch panel control substrate of a touch panel device that uses an electrostatic capacitance method.

### REFERENCE SIGNS LIST

1, 901 touch panel device
10 touch panel main body
20 touch panel control substrate
23, 24, 26 connector
100, 200, 300, 400, 500, 600, 700, 800, 900 touch panel controller
101A, 102A, 103A drive line drive circuit (drive circuit)
111B, 112B, 113B sense line drive circuit (drive circuit)
301A, 302A, 303A drive line drive circuit (drive circuit)
331 sense line drive circuit (drive circuit)
501A, 502A, 503A drive line drive circuit (drive circuit)
531 sense line drive circuit (drive circuit)
701A, 702A, 703A, 704A wiring line drive circuit (drive circuit)
905 driver (drive circuit)
101B, 102B, 103B drive line voltage measuring circuit (detection unit, voltage measuring unit)
111C, 112C, 113C sense line voltage measuring circuit (detection unit, voltage measuring unit)
330 voltage measuring circuit (detection unit, voltage measuring unit)
101E, 102E, 103E drive line terminal (connection terminal)
111F, 112F, 113F sense line terminal (connection terminal)
301E, 302E, 303E drive line terminal (connection terminal)
311F, 312F, 313F sense line terminal (connection terminal)
501E, 502E, 503E drive line terminal (connection terminal)
511F, 512F, 513F sense line terminal (connection terminal)
701E, 702E, 703E, 704E wiring line terminal (connection terminal)
111A, 112A, 113A sense line capacitance detection circuit (detection unit, electrostatic capacitance measuring unit)
311A, 312A, 313A sense line capacitance detection circuit (detection unit, electrostatic capacitance measuring unit)
511A, 512A, 513A sense line capacitance detection circuit (detection unit, electrostatic capacitance measuring unit)
530 drive line capacitance detection circuit (detection unit, electrostatic capacitance measuring unit)
701B, 702B, 703B, 704B wiring line capacitance detection circuit (detection unit, electrostatic capacitance measuring unit)
906 sense amplifier (detection unit, electrostatic capacitance measuring unit)
123 voltage measurement result determination circuit (detection unit, operation unit)
123A voltage measurement result determination circuit (detection unit, first operation unit)
123B voltage measurement result determination circuit (detection unit, second operation unit)
323 voltage measurement result determination circuit (detection unit, operation unit)
323A voltage measurement result determination circuit (detection unit, first operation unit)
323B voltage measurement result determination circuit (detection unit, second operation unit)
523 capacitance measurement result determination circuit (detection unit, operation unit)
523A capacitance measurement result determination circuit (detection unit, first operation unit)
523B capacitance measurement result determination circuit (detection unit, second operation unit)
723 capacitance detection result determination circuit (detection unit, operation unit)
723A capacitance measurement result determination circuit (detection unit, first operation unit)
723B capacitance measurement result determination circuit (detection unit, second operation unit)
Cx capacitance value (electrostatic capacitance value)

1-8. (canceled)

9. An inspection method for a touch panel control substrate including a touch panel controller that supplies, via a connector, a drive signal to a plurality of signal lines provided in a touch panel main body, comprising
a supplying step of supplying the drive signal to a plurality of connection terminals each of which is electrically connected to each of the signal lines via the connector, and
a detecting step of detecting, on the basis of each response obtained, in response to the drive signal supplied to a connection terminal among the connection terminals, in connection terminals other than the connection terminal, an electrical connection state between the connection terminal and each of the other connection terminals.

10. The inspection method for a touch panel control substrate according to claim 9, wherein
the detecting step includes
a voltage measurement result outputting step of outputting, in accordance with a voltage of each of the other connection terminals at a time of supplying the drive signal to the connection terminal, any one of two value signals each of which corresponds to presence or absence of an electrical connection between the connection terminal and the other connection terminals, and
an operation step of executing an operation for signals each of which (i) corresponds to each of the connection terminals and (ii) has been the signal outputted in the voltage measurement result outputting step.

11. An inspection method for a touch panel control substrate including a touch panel controller that supplies, via a connector, a drive signal to a plurality of signal lines provided in a touch panel main body, comprising
a supplying step of supplying the drive signal to a connection terminal that is electrically connected to the signal lines via the connector, and
a detecting step of measuring an electrostatic capacitance value of the connection terminal to which the drive signal is supplied and detecting, on the basis of the electrostatic capacitance value, an electrical connection state between the connection terminal and each of other connection terminals.

12. The inspection method for a touch panel control substrate according to claim 11, wherein
the connection terminals are arrayed in rows, and
at the supplying step, mutually different drive signals are supplied to the connection terminals that are adjacent to each other, and
at the detecting step, on the basis of an electrostatic capacitance value of each of the connection terminals, an electrical connection state between the connection terminal and a connection terminal that is adjacent thereto is detected.

13. The inspection method for a touch panel control substrate according to claim 11, wherein
the supplying step includes
a first supplying step of supplying a first drive signal to a first connection terminal group that is composed of some connection terminals of the plurality of connection terminals, and
a second supplying step of supplying a second drive signal that is different from the first drive signal to a second connection terminal group that is composed of other connection terminals of the plurality of connection terminals, and
at the detecting step, on the basis of an electrostatic capacitance value of each of the connection terminals included in the first connection terminal group, an electrical connection state between the connection terminal and each of the connection terminals included in the second connection terminal group is detected.

14. A touch panel controller that supplies, via a connector, a drive signal to a plurality of signal lines provided in a touch panel main body, comprising
a plurality of connection terminals each of which is electrically connected to each of the signal lines via the connector,
a drive circuit that supplies the drive signal to the connection terminals, and
a detection unit that detects, on the basis of each response obtained, in response to the drive signal supplied to a connection terminal among the connection terminals, in connection terminals other than the connection terminal, an electrical connection state between the connection terminal and each of the other connection terminals.

15. The touch panel controller according to claim 14, wherein
the detection unit includes
a voltage measuring unit that outputs, in accordance with a voltage of each of the other connection terminals at a time of supplying the drive signal to the connection terminal, any one of two value signals each of which corresponds to presence or absence of an electrical connection between the connection terminal and each of the other connection terminals, and
an operation unit that executes an operation for signals each of which (i) corresponds to each of the connection terminals and (ii) has been the signal outputted from the voltage measuring unit.

16. The touch panel controller according to claim 14, wherein
the detection unit includes
an electrostatic capacitance measuring unit that measures an electrostatic capacitance value of each of the other connection terminals and outputs, on the basis of the electrostatic capacitance value, any one of two value signals each of which corresponds to presence or absence of an electrical connection between the connection terminal and each of the other connection terminals, and
an operation unit that executes an operation for signals each of which (i) corresponds to each of the connection terminals and (ii) has been the signal outputted from the electrostatic capacitance measuring unit.
